(19) United States
(12) Patent Application Publication
(10) Pub. No.: US 2026/0094261 A1
(43) Pub. Date: Apr. 2, 2026

(54) SEMICONDUCTOR EXPOSURE METHOD AND SEMICONDUCTOR EXPOSURE SYSTEM FOR PERFORMING THE SEMICONDUCTOR EXPOSURE METHOD

(71) Applicant: SK hynix Inc., Icheon-si (KR)

(72) Inventors: Dong Woo HAN, Icheon-si (KR); Hyun Jin CHO, Icheon-si (KR)

(21) Appl. No.: 19/190,463

(22) Filed: Apr. 25, 2025

(30) Foreign Application Priority Data
Sep. 27, 2024 (KR) 10-2024-0131819

(51) Int. Cl. G06T 7/00; G01N 23/2251; G03F 7/00

(52) U.S. Cl. CPC G06T 7/001; G01N 23/2251; G03F 7/705; G03F 7/70508; G03F 7/70516; G03F 7/70525; G03F 7/70625; G03F 7/70655; G03F 7/706837; G01N 2223/401; G01N 2223/6116

(57) ABSTRACT

A semiconductor exposure method may include forming a pattern on a wafer using a light source in a semiconductor exposure equipment, collecting a pattern image of the pattern to be analyzed, deriving a pixel histogram of the pattern image, and using the pixel histogram to calculate a dark or white value (DW value) of the pattern image, and comparing the DW value of the pattern image with reference focus information to determine whether an outlier has occurred in the pattern to be analyzed due to defocusing of the laser light.

### CROSS-REFERENCE TO RELATED APPLICATION

The present application claims priority under 35 U.S.C. § 119(a) to Korean application number 10-2024-0131819, filed on, Sep. 27, 2024, in the Korean Intellectual Property Office, which is incorporated herein by reference in its entirety.

### BACKGROUND

### 1. Technical Field

Example embodiments relate to a semiconductor exposure method and a semiconductor exposure system for performing the semiconductor exposure method.

### 2. Related Art

In recent years, as a critical dimension (CD) of semiconductor patterns may have become smaller while the density of semiconductor devices may have increased. In general, to manufacture highly integrated semiconductor devices, it may be necessary to form microscopic semiconductor patterns precisely at desired locations. In addition, establishing stable patterning conditions for forming patterns with high CD uniformity (i.e., critical dimension uniformity) may be an important factor in manufacturing processes of highly integrated semiconductor devices. Accordingly, various methods to improve pattern overlay and CD uniformity have been researched and developed in recent years.

A semiconductor device may be fabricated by a patterning process. A typical patterning process may be performed by irradiating a laser light on top of a mask, collecting the laser light that has passed through the mask, and transcribing a mask pattern onto a wafer. In the patterning process, the focus position of the laser light, focused through a lens to accurately match a surface of the wafer, is important to form deep, clear, and noise-free patterns. In other words, in the patterning process, the accurate focus position of the laser light may be an important factor in improving reliability of the fine pattern formation. In particular, when a plurality of semiconductor patterns with various critical dimensions and shapes are combined and transcribed on the wafer through a patterning process, it is efficient to use a patterning process at a laser focus position for all of the semiconductor patterns. When the laser focus position is inconsistent or inaccurate, some of the plurality of patterns might not be transcribed in the correct position and shape.

In order to derive an optimal focus position of the laser, a method utilizing a Bossung Curve may be traditionally used. The method of utilizing the Bossung Curve may be as follows. First, a pattern may be transcribed to a wafer. A pattern image of the transcribed pattern may then be collected. Then, a critical dimension of the pattern may be measured from the pattern image. At this point, the pattern image may be collected using different focus positions to collect a plurality of pattern images. Then, a critical dimension of the pattern may be measured for each of the plurality of collected pattern images and the Bossung curve may be derived using the plurality of measured critical dimensions. An inflection point may be selected from the derived Bossung curve. The position of the inflection point may be used to derive the optimal focus.

However, since the method utilizing the Bossung curve may be based on a critical dimension, which may be a length of a specific part of a specific semiconductor pattern, it may be difficult to obtain the same patterning results for all patterns when transcribing various types of patterns on a single wafer using the critical dimension.

Further, a method utilizing the Bossung curve may be only effective for a limited number of semiconductor patterns in the form of quadratic functions with inflection points. In addition, achieving an optimum focus position using a Bossung curve may have low reliability when there are significant changes in the shape of the curve depending on the wafer state, process, and equipment conditions. Thus, it may be difficult to achieve desired important characteristics for each pattern. Furthermore, while a Bossung curve continues to be utilized, the critical dimension may be continuously reduced due to the increasing density of semiconductor devices, and as a result error in the optimal focus may increase. Research on a new method to address the above problems is necessary.

In general, various types of semiconductor patterning equipment may be utilized to mass produce semiconductor devices. The patterning equipment may differ from each other in terms of manufacturer, equipment conditions, etc. Furthermore, the semiconductor device may utilize wafers in different states depending on the purpose of wafer use. The semiconductor patterning equipment may have a structure capable of performing a patterning process utilizing laser light.

In the patterning process, it may be necessary to have an objective method of deriving the same patterning process performance by reflecting various requirements such as wafer condition, patterning process condition, equipment manufacturer, etc. However, no objective method for evaluating patterning process performance may be currently available. As a result, it may take excessive time, effort, and cost to compare and synchronize process performance among different semiconductor patterning equipment, or to improve processes by analyzing causes of errors such as an outlier pattern formation error due to focus position changes.

### SUMMARY

According to example embodiments, by calculating a DW value (Dark or White Value) that numerically expresses a change in the focus position of a light source from a pixel histogram of a pattern image to evaluate the focus position, a semiconductor exposure method and a semiconductor exposure system for the same may accurately derive an outlier caused by an excessive change in focus, the level of the outlier, and the time of the outlier.

According to example embodiments, the present disclosure may provide a semiconductor exposure method and a semiconductor exposure system for exposure of semiconductors with high generalizability as the DW value may clearly numerically express the complex physical phenomena and the results of the patterning process due to the change of the laser's focus, enabling generalization of the focus position evaluation even when various semiconductor exposure equipment of different manufacturers are utilized.

According to example embodiments, it may be intended to provide a semiconductor exposure method and a semiconductor exposure system for exposure that may accurately identify a defocus trend of a semiconductor exposure process and objectively compare the actual process performance differences of each of a plurality of semiconductor exposure equipment and the condition differences between processes without relying on the subjective judgment of a person in charge.

According to example embodiments, the present disclosure may provide a semiconductor exposure method and a semiconductor exposure system for exposure that may analyze the correlation of patterning conditions and outlier generation factors of exposure equipment to the focus position of a light source and pattern image changes, and generate an AI-based machine learning model that may accurately extract focus change characteristics from pattern images and provide reliable outlier prediction results and improvement levels.

According to example embodiments, a semiconductor exposure method and a semiconductor exposure system for exposure are provided that may accurately adjust the focus position of a light source when an outlier is caused by defocusing the light source, thereby forming a clear ultra-fine pattern at a precise location.

There may be provided a semiconductor exposure method in accordance with example embodiments. In the semiconductor exposure method, a pattern may be formed on a wafer using a light source in semiconductor exposure equipment. A pattern image of the pattern to be analyzed may be collected. A pixel histogram of the pattern image may be derived. A dark or white value (DW value) of the pattern image may be calculated using the pixel histogram. The DW value of the pattern image may be compared with reference focus information to determine whether the light source may be defocused, resulting in an outlier in the pattern to be analyzed.

There may be provided a semiconductor exposure system. The semiconductor exposure system may include a pattern former, an image collector and an outlier detector. The pattern former may form a pattern on a wafer by performing an exposure process. The image collector may collect a pattern image of the pattern to be analyzed. The outlier detector may derive a pixel histogram of the pattern image. The outlier detector may calculate a dark or white value (DW value) of the pattern image using the pixel histogram. The outlier detector may compare the DW value of the pattern image with reference focus information to determine whether an outlier may be generated in a focus of a light source in the pattern former.

According to example embodiments, the semiconductor exposure method may derive the pixel histogram from the pattern image of the pattern to be analyzed, and calculates the DW value of the pattern using the derived pixel program. The DW value of the pattern may clearly numerically express a level of change of complex physical interactions due to a focus change of the light source, so that an outlier of the pattern caused by the excessive change of focus, the level of outlier of the pattern, and the time when the outlier of the pattern occurs may be accurately derived.

According to example embodiments, the semiconductor exposure method may be highly versatile because, even when utilizing various semiconductor exposure equipment of different manufacturers, the DW value of the pattern may clearly numerically express the level of change of the complex physical interactions due to the focus change of the laser, thereby enabling generalization of the focus position evaluation by exposure equipment.

According to example embodiments, the semiconductor exposure method may accurately identify a defocus trend of the semiconductor exposure equipment, and may objectively compare an actual process performance difference of each of the plurality of exposure equipment and the condition difference between the processes without relying on the subjective judgment of the person in charge.

According to example embodiments, the semiconductor exposure method may analyze the correlation between the patterning conditions and outlier generation factors of the exposure equipment on the focus of the light source and the pattern image change, and may accurately extract the characteristics of the focus change from the pattern image, and provide reliable outlier prediction results through machine learning based on AI.

According to example embodiments, the semiconductor exposure method may be adjusted to place the focus of the light source at an optimal focus position in the event of defocus, thereby forming a sharp ultra-fine pattern at a precise location on the wafer.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a CD-SEM pattern image illustrating an example of a pattern formed on a wafer;

FIG. 2 is an example of a Bossung curve showing a correlation between a laser focus and a critical dimension in a form of a quadratic function by forming a pattern at 10 different focus positions, measuring a critical dimension of a generated pattern, and approximating the Bossung curve;

FIG. 3 is an example of pattern-specific complementarity curves for each pattern, computed from pattern images of five random patterns;

FIG. 4A is a schematic view illustrating a photolithography process at an optimal focus position (f=0);

FIG. 4B is a schematic view illustrating a photolithography process at negative focus (f<0);

FIG. 4C is a schematic view illustrating a photolithography process at positive focus (f>0);

FIG. 5 is a process diagram illustrating a semiconductor exposure method in accordance with embodiments of the disclosure;

FIG. 6 is a block diagram illustrating semiconductor exposure equipment in accordance with embodiments of the disclosure;

FIG. 7A is a CD-SEM pattern image showing a pattern formed by performing an exposure process at an optimal focus position in accordance with example embodiments;

FIG. 7B is a CD-SEM pattern image showing a pattern formed by performing an exposure process at a defocused focus position in accordance with example embodiments;

FIG. 8 is an image showing a histogram of pixels by focus location, calculated after forming a pattern having the same shape and threshold magnitude as in FIG. 7A at a total of 11 focus locations (FOCUS1 through FOCUS11), in accordance with example embodiments;

FIG. 9 is a DW curve calculated by calculating a focus position-specific DW value from a pattern image of a pattern comprising one sub-pattern, transforming the calculated focus position-specific DW value into a quadratic function, and generating a correction curve that approximates the DW curve, in accordance with example embodiments;

FIG. 10 is a graph illustrating DW values for each day of an exposure process;

FIG. 11A is a state view illustrating a creation of a window in a pattern image of a pattern to be analyzed, in accordance with embodiments of the disclosure;

FIG. 11B illustrates a window created in a pattern image of a pattern to be analyzed using an SSIM technique for comparison, in accordance with embodiments of the disclosure;

FIG. 12 shows results of repeatedly performing an exposure process to form a pattern on a wafer utilizing different semiconductor exposure equipment in accordance with example embodiments of the disclosure;

FIG. 13 is a pattern image collected from five patterns with different shapes and thresholds in accordance with example embodiments of the disclosure;

FIG. 14 is a focus graph generated by forming each of the five patterns of FIG. 13 with different shapes and thresholds at each of the eleven focus locations and then deriving a histogram scatter function for each of the five sub-patterns in accordance with embodiments of the disclosure;

FIG. 15 is an approximation-corrected graph of the focus-by-focus graph of FIG. 14;

FIG. 16 illustrates a derivative of the approximate calibration graph in FIG. 15 at an arbitrary focus position;

FIG. 17 is a focus graph and its approximation correction graph for a pattern set comprising the five patterns as a whole, calculated by weighted averaging the derivatives of FIG. 15; and

FIG. 18 is a block diagram illustrating a semiconductor exposure system in accordance with embodiments of the disclosure.

### DETAILED DESCRIPTION

Embodiments of the present disclosure are hereinafter described in detail, with reference to the drawings, to facilitate practice by one of ordinary skill in the art to which the disclosure belongs. However, the present disclosure may be implemented in many different forms and is not limited to the embodiments described herein. In connection with the description of the drawings, the same or similar reference numerals may be used for the same or similar components. Further, in the drawings and associated description, descriptions of well-known features and configurations may be omitted for clarity and brevity.

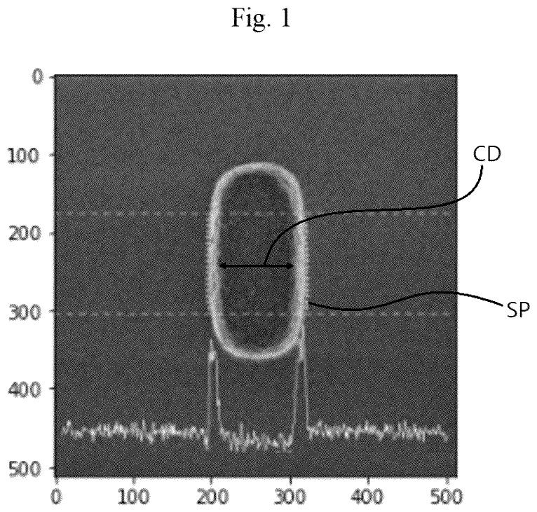

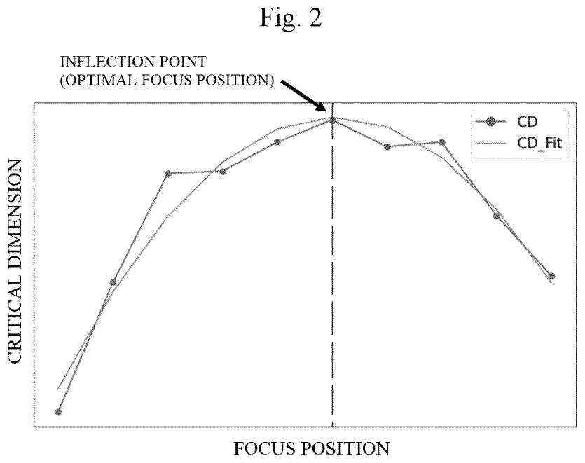

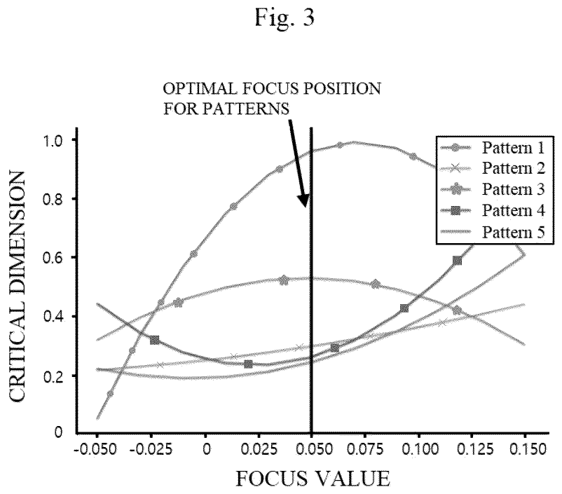

FIG. 1 is a CD-SEM pattern image illustrating an example of a pattern formed on a wafer. FIG. 2 is an example of a Bossung curve showing a correlation between a laser focus and a critical dimension in a form of a quadratic function by forming a pattern at 10 different focus positions, measuring a critical dimension of a generated pattern, and approximating the Bossung curve. FIG. 3 is an example of pattern-specific complementarity curves for each pattern, computed from pattern images of five random patterns.

Referring to FIG. 1, a critical dimension (CD) is indicated by a double-headed arrow may be measured at an arbitrary position of a pattern formed by a photolithography process. After sequentially transcribing the pattern by changing the laser focus position multiple times, pattern images may be collected for each focus position, and the critical dimension may be measured for each of the collected multiple pattern images. The critical dimensions obtained from the multiple collected pattern images are used to derive an optimal focus position for an exposure process for transcribing a pattern on a wafer.

Then, as shown in FIG. 2, a Bossung curve may be derived, which may be a function of a correlation between a laser focus position and a corresponding critical dimension. In the Bossung curve, when an X-axis value of an inflection point position changes significantly from side to side, a Y-axis value representing the critical dimension may have a minimum change. Traditionally, the X value at the inflection point position in the Bossung curve may be determined as the optimal focus position. For example, the Bossung curve of FIG. 2 may be calculated by changing the focus position and collecting a plurality of pattern images from patterns formed by each different focus position, and measuring the critical dimensions of the pattern images corresponding to different focus positions. CD, shown in FIG. 2, refers to a complementary linear curve that represents the result of measuring the threshold dimension by focus position at different focus positions. A CD fit, shown in FIG. 2, may refer to the result of approximating the linear Bossing curve.

However, the Bossung curve may be fit using a quadratic function, which means that it may only yield the optimal focus position when the inflection point, a point of convex or concave protrusion, is clearly visible.

In particular, in the manufacture of semiconductor devices, a plurality of semiconductor patterns with various critical dimensions and shapes may be sometimes combined and transcribed to form a single pattern.

In such conventional cases, as shown in FIG. 3, in order to derive a focus position for accurately and clearly transcribing all of the plurality of patterns, a critical dimension for each pattern may be measured, and a Bossung curve may be generated for each pattern, respectively. Then, using the plurality of pattern-specific Bossung curves, the optimal focus position may be determined using any method, such as an average value.

As mentioned above, conventional methods utilizing Bossung curves may be based on the critical dimension, which may be a measured length of a arbitrary region of a semiconductor pattern. As a result, the conventional methods utilizing Bossung curves might not represent patterning results for all patterns formed in the entire image area. Furthermore, conventional methods utilizing the Bossung curves may have difficulty deriving accurate optimal focus locations because, as pattern sizes are miniaturized to the nanometer scale, such methods result in poor process and product quality.

In particular, conventional methods utilizing the Bossung curves may arbitrarily select a location of the pattern image to measure the critical dimension. Since the critical dimension collected from this single location may be used to represent the entire pattern, when deriving the Bossung curve showing the correlation between the critical dimension and the focus position, it may often happen that the derived Bossung curve might not show a quadratic function. In other words, as shown in FIG. 3, the Bossung curve derived from a specific pattern might not show an inflection point, making it difficult to determine the optimal focus. In addition, there may be many cases where the Bossung curve might not be derived at all because the critical dimension might not be calculated, which is a major obstacle to deriving the optimal focus.

Conventional methods utilizing the Bossung curve may have a very limited utility because the methods only manage changes in threshold dimension values and may only check the actual pattern image when an outlier occurs in the pattern.

In addition, when the laser focus level is maintained in conventional methods utilizing the Bossung curve, the patterning result may be checked individually, so the exposure process may be managed by monitoring for changes in the critical dimension of the pattern based on the use of a Bossung curve established for only some semiconductor patterns. In other words, when an outlier critical dimension occurs, the exposure process may include checking whether the semiconductor pattern is clearly transferred to the correct position on the pattern image in outlier cases.

In addition, conventional methods utilizing the Bossung curve may have a problem with difficulty in identifying when the focus change occurs and the level of the focus change. In conventional methods utilizing the Bossung curve, it may be difficult to recognize the process problem immediately because it might not be possible to accurately confirm the focus change, and even when a problem occurs resulting in a large change in laser focus, it may be confirmed that there is no trend change in the critical dimension value. Furthermore, it may be difficult to recognize the onset and level of focus change, which increases the difficulty of analyzing the cause and delays to improve the focus level, forcing the use of indirect methods of adjusting the energy of the laser to solve the problem.

Furthermore, conventional methods utilizing the Bossung curve have a disadvantage in finding the cause of the laser focus change, or to predict the process tendency and the time and level of the outliers, to prevent accidents. Since the focus of the laser may fluctuate by only a few nanometers, a wide variety of uncontrollable factors, such as the results of pre-processes such as deposition processes performed before the exposure process, process setting conditions, equipment setting conditions, or equipment vibration, can affect the laser focus. Due to the complex interaction of numerous factors as described above, the most effective way to find and improve the true causes that significantly affect laser focus change is to build a highly consistent model that may calculate the contribution (feature importance) based on the correlation between parameters such as machine learning and deep learning. However, a system that utilizes the conventional Bossung curve-based critical dimension may have a problem in that the critical dimension is a measurement of the length of a specific part of the pattern on the pattern image, which has a large scatter. As a result, it is difficult to derive a robust and reliable model function that may accurately identify the root cause of the focus change. This makes it difficult to apply data science for process and equipment accident prevention and makes it difficult to predict process trends and the timing and level of anomalies.

Furthermore, conventional methods utilizing the Bossung curve may become unreliable with the continuous development of micro-fabrication technology. Because the size of semiconductor patterns has decreased in recent years, when the critical dimension value is relied on, a significant increase in the critical dimension error in micro-semiconductor patterns causes the laser focus change to intensity, and the reliability of the system decreases, making it difficult to utilize.

For the above reasons, it is necessary to develop a new system that manages pattern outlier data, analyzes the main outlier generating factors that affect focus change, and improves focus change by utilizing DW (dark or white value) values that may directly represent the focus of the light source.

An embodiment of a semiconductor exposure method may detect an outlier in a semiconductor exposure process by tracking changes in a DW value of a pattern image. Further, a semiconductor exposure method according to an embodiment may provide a method for identifying anomalous factors that affect anomalous generations and improving anomalous factors that cause focus changes.

Furthermore, a semiconductor exposure method according to an embodiment may prevent exposure process and equipment accidents by building a machine learning model based on a correlation between the DW value of a pattern image and a major outlier generation factor that has a significant impact on the DW value change of the pattern image, so that the tendency of the DW value data of the pattern image, the time of outlier generation, and the level of outlier generation may be predicted.

In general, the best focus of a light source is the location of a specific point where all the light that has passed through the lens is gathered when performing the exposure process. On the other hand, a light source is defocused when the light that has passed through the lens is scattered and not concentrated at a specific point.

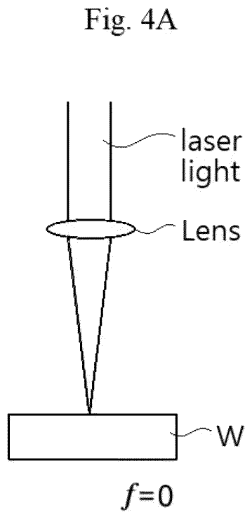

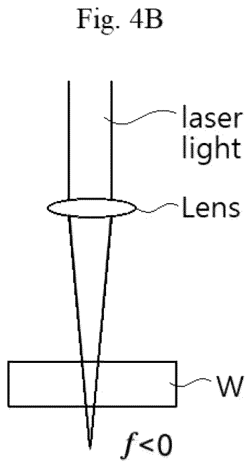

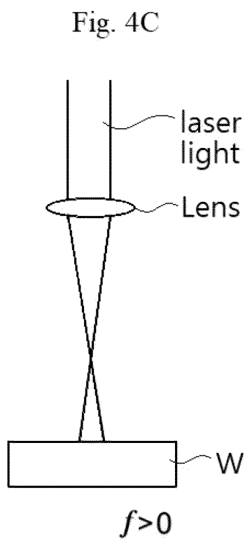

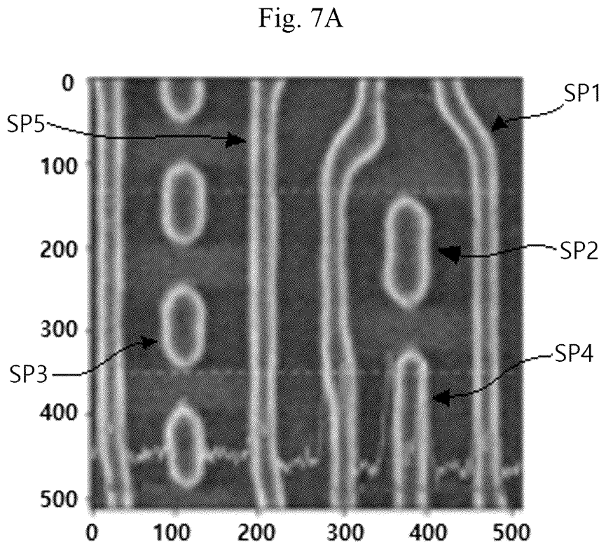

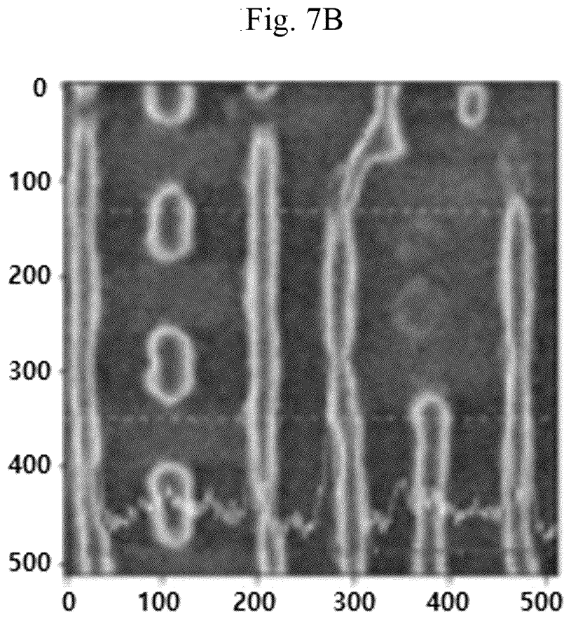

FIG. 4A is a schematic view illustrating a photolithography process at an optimal focus position (f=0). FIG. 4B is a schematic view illustrating a photolithography process at negative focus (f<0). FIG. 4C is a schematic view illustrating a photolithography process at positive focus (f>0). FIG. 7A is a CD-SEM pattern image showing a pattern formed by performing an exposure process at an optimal focus position in accordance with example embodiments. FIG. 7B is a CD-SEM pattern image showing a pattern formed by performing an exposure process at a defocused position in accordance with example embodiments.

Referring to FIG. 4A, in an optimal focus position, a laser light may be focused on a surface of a wafer W at a suitable distance between the laser light and the lens. Referring to FIG. 4B, in a negative defocus position, the distance between the laser light and the lens may be improper, resulting in focusing on an interior of the wafer W or a position under the wafer W. Referring to FIG. 4C, in a positive defocus position, the laser light may be focused above the wafer W because of an unsuitable distance between the laser light and the lens.

The light source may have different sharpness and shape on the transcribed pattern depending on the focus position. When an exposure process is performed at a defocused position (see FIG. 7B), the width of lines forming the pattern in the pattern image may vary, or a sharpness of the lines may decrease, as opposed to when the exposure process is performed at an optimal focus position (see FIG. 7A). Also, the pattern may be formed on the wafer in a different shape than the intended shape when a defocused position is used. Negative pattern characteristics may exhibit a tendency to increase in proportion to the distance between the optimal focus position and the defocus position.

The semiconductor exposure methods of example embodiments may be utilized to manage the focus of the light source, particularly in a semiconductor patterning process utilizing the laser light source to detect the optimal focus position and determining whether an error should be generated. Semiconductor exposure methods of example embodiments may be applied to a patterning process for forming a pattern on a substrate to manufacture a semiconductor device. The semiconductor exposure methods of example embodiments may be performed using a computer program in a non-transitory computer readable medium storing computer programs.

Further, semiconductor exposure methods of example embodiments may be utilized to determine whether an outlier exists in the semiconductor exposure equipment, and may contribute to yield improvements by calculating an optimal focus position.

In the following examples, semiconductor exposure methods of embodiments will be described in more detail.

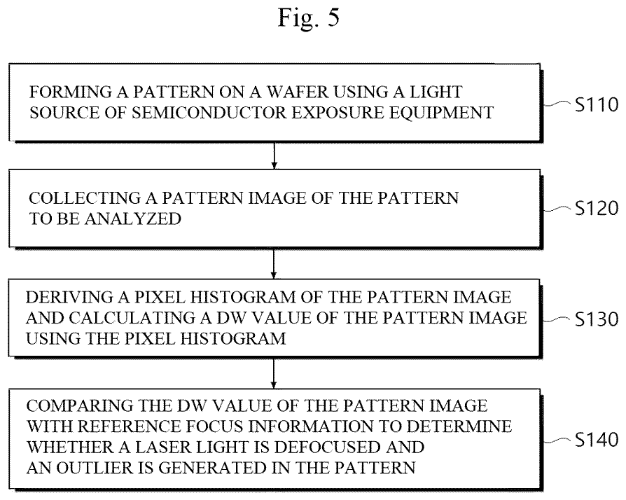

FIG. 5 is a process diagram illustrating a semiconductor exposure method in accordance with embodiments of the disclosure.

Referring to FIG. 5, a semiconductor exposure method may include step S110 for forming a pattern on a wafer; step S120 for collecting a pattern image of the pattern to be analyzed; step S130 for calculating a DW value (dark or white) of the pattern image; and step S140 for determining whether an outlier may be generated in the pattern to be analyzed. In step S110 for forming the pattern on the wafer, a light may be generated using semiconductor exposure equipment, and a photolithography process may be performed using the generated light to form a pattern on the wafer.

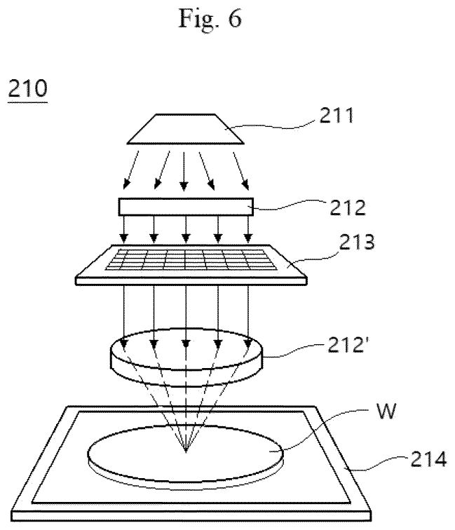

FIG. 6 is a block diagram illustrating semiconductor exposure equipment of in accordance with embodiments of the disclosure. FIG. 7B is a CD-SEM pattern image of a pattern formed by performing an exposure process at a defocused focus position, in accordance with example embodiments.

Referring to FIG. 6, semiconductor exposure equipment may be implemented using laser-based semiconductor exposure equipment having a conventional variety of structures, including a light source 211 configured to generate a light, lenses 212 and 212′ configured to adjust a focus of the light, a mask 213 on which a transcribing pattern may be formed, and a stage 214 on which the wafer W may be movably mounted. The semiconductor exposure equipment illustrated in FIG. 6 can function as a pattern former 210 in the semiconductor exposure system 200 to be described later.

The light source 211 may be a laser light source. The laser light source 211 may include at least one of a KrF excimer laser light source, an ArF excimer laser light source, an ArFi laser light source, an EUV laser light source, etc.

Referring again to FIG. 1 and FIG. 5, in step S110 sub-patterns, such as sub-pattern SP in FIG. 1, of substantially the same shape as seen in FIG. 7A may be formed on the wafer W. Accordingly, the pattern image of the pattern to be analyzed may identify at least one or more sub-patterns having the same or substantially the same shape.

Alternatively, referring to FIG. 7A, in step S110, a pattern may be formed on the wafer W including a plurality of sub-patterns SP1 to SP5, where at least one of the shapes and the critical dimension scale may be different from each other. Accordingly, the pattern image of the pattern under analysis may identify a set of patterns characterized by the formation of a plurality of at least two sub-patterns SP1 to SP5 having different shapes.

Furthermore, in step S110, a plurality of semiconductor exposure equipment may be used to form the patterns on a plurality of wafers W, respectively. The plurality of semiconductor exposure equipment may be of different manufacturers, different patterning conditions, etc. The plurality of semiconductor exposure equipment may each independently perform the exposure process to simultaneously form a plurality of patterns having the same general characteristics.

Next, in step S120 for collecting a pattern image of the pattern to be analyzed, the pattern image of the pattern to be analyzed among the patterns formed on the wafer W may be collected using the semiconductor exposure equipment.

In step S120, the pattern image of the pattern to be analyzed may be collected using various types of equipment conventionally utilized for photographing patterns in an exposure process for manufacturing semiconductor devices.

Specifically, a critical dimension scanning electron microscope (CD-SEM) device may be used to collect CD-SEM pattern images of the pattern of interest for analysis.

The CD-SEM device may inject electrons into the pattern and generate a pattern image using the emitted electrons reflected from the pattern. When a change in laser focus occurs in the exposure process, the CD-SEM pattern images may be used to calculate the level of change in laser focus based on the level of change in the engraved pattern. This method is superior to measurements taken during transcribing the micro-pattern in a photolithography process because the location where the light generated by the light source may be concentrated needs to be determined and then the exposure process performed at that location. Since the lens utilized to concentrate the light in the photolithography process may be made of glass, it might not be possible to install a sensor on the lens, and when it is installed in a path of the light, it may block light generated by the light source. In addition, it may be difficult to accurately measure the focus of the light using only a mechanical method. For these reasons, the optimal focus of the light source may be more advantageously derived using CD-SEM images of the pattern.

Again, referring to FIG. 7A, a CD-SEM pattern image acquired by patterning at the optimal focus position may show a deep, sharp, and low-noise pattern on the wafer W.

Specifically, when a semiconductor pattern is formed by performing an exposure process at an optimal focus position, light and energy may be concentrated at the optimal focus position. As a result, a pattern image collected at that focus location may show a pattern that may be deep, sharp, and characterized by low ambient noise.

In contrast, referring to FIG. 7B, a pattern image collected by forming a pattern at a defocus position may show a pattern with unclear lines and shapes and a noisy pattern. Specifically, when a semiconductor pattern is formed by performing an exposure process at a defocus position that may be unsuitable for the exposure process, light and energy may be dispersed. As a result, a pattern image collected at the corresponding focus position may show a pattern that is not accurately transcribed, with sub-patterns exhibiting irregular or unclear shapes, and a pattern that may be noisy and blurry in character.

As mentioned above, depending on the focus position of the light source for pattern formation, the sharpness, depth, noise, and shape (breakage) of the pattern seen in the pattern image may have different characteristics.

Therefore, by collecting information about the image level for each pattern image, it may be possible to determine a process compliance level or an optimal focus position of the light source. However, it may be difficult to determine with great accuracy, using only the human visual means, the differences between the pattern images for the patterns generated at the optimal focus and defocus positions as shown in FIGS. 7A and 7B. Accordingly, in the steps that follow, statistical methods, such as pixel histograms, DW values, and DW curves, may be utilized to calculate the optimal focus position.

It should be noted that pixel histograms may be calculated from the entire pattern image of FIGS. 7A and 7B, and not only from a single sub-pattern SP. In the following examples, light generated by the light source will be described as laser light.

Next, in step S130 for calculating a dark or white value of a pattern image, a pixel histogram of the pattern image may be derived, and the pixel histogram may be used to calculate a DW value of the pattern image.

In the present disclosure, the DW value may mean a scatter (Standard Deviation (SD)) of a histogram of a pattern image. Although not a conventionally utilized term, the DW value may be a term that describes a semiconductor exposure method in example embodiments. The DW value may be calculated by averaging the number of brightness values in the pixel histogram and displaying it as a single value. The DW value may be calculated one for each pattern image. Specifically, in the exposure process, the pattern is formed into different shapes depending on the focus position of the light source. If the pattern is formed at multiple different focus positions, different DW values are calculated for each collected pattern image for each focus position.

The DW value may be calculated in the following way. First, a pattern image of the pattern to be analyzed may be segmented into pixels. Then, brightness values of the segmented pixels may be converted into a statistical pixel histogram. The DW value representing the converted pixel histogram may be calculated. A single DW value may be calculated for each pattern image.

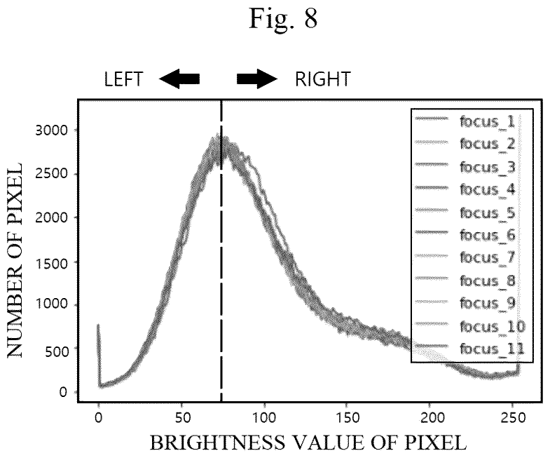

FIG. 8 is an image showing a histogram of pixels by focus location, calculated after forming a pattern having the same shape and threshold magnitude as in FIG. 7A at a total of 11 focus locations (FOCUS1 through FOCUS11), in accordance with example embodiments.

Referring to FIG. 8, a focus position may be adjusted to result to different positions corresponding to different separation distances between the laser source and the lens. For example, the focus position may be changed into 11 different exemplary focus positions, which consider the separation distance between the laser light source and the lens The focus position may be selectively divided to enable a calculated a pixel histogram for each focus position. By adjusting the focus position as described above and calculating the pixel histogram, the DW value, which may be a scattering function of the pattern image, may be derived respectively for each focus position.

In the pixel histogram, the x-axis may represent a pixel number ranging from about 0 to about 255. The pixel number may mean a brightness value of each of the segmented pixels in the pattern image. In the pixel histogram, the y-axis may represent a count of the number of pixels with a certain characteristic may be present in the pattern image. For example, the pixel histogram may be used for counting how many pixels with a certain brightness value may be present in a pattern image.

The pixel histogram may represent a statistical characterization of a pattern transcribed in the pattern image, i.e., a pixel histogram for the pattern image may be derived using the brightness values of the pixels displayed in the pattern image and the number of pixels per brightness value. Then, using the pixel histogram, a DW value expressing a characteristic of the pattern image may be calculated.

Next, the DW values for each focus position may be converted into a quadratic function to produce a DW curve (Dark or White curve). The resulting DW curves may be utilized to derive the optimal focus position.

Specifically, as described herein, the DW curves may indicate the level of aggregate physical interaction as a function of changing the focus position of the laser light.

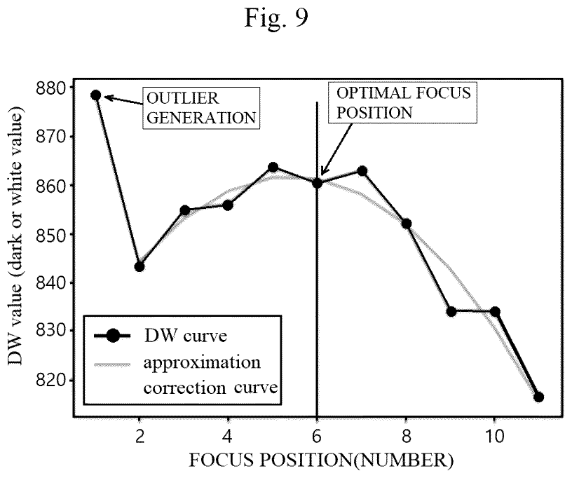

FIG. 9 is a DW curve calculated by calculating a focus position-specific DW value from a pattern image of a pattern comprising one sub-pattern, transforming the calculated focus position-specific DW value into a quadratic function, and generating a correction curve that approximates the DW curve, in accordance with example embodiments. The pattern formed through the exposure process can have various shapes. The sub-pattern is only an example to explain that the pattern can have various shapes. One pixel histogram and DW value are calculated from one entire pattern image. In other words, the pixel histogram and DW value are not calculated by dividing each sub-pattern.

Referring to FIG. 9, a DW curve may be derived from pattern images formed at different focus positions. The DW curve may be generated, after generating patterns for different focus positions and analyzing pattern image collected from the patterns, by calculating DW values for each focus position, and connecting the calculated DW values at each focus position.

The DW curve may be calculated in the following way. First, the same pattern may be formed repeatedly while changing the focus position of the laser light. Next, pattern images by focus position for each of the plurality of patterns may be collected. Next, the DW values for each focus position may be calculated from the collected pattern images, and the DW curve may be calculated by converting the calculated DW values at each focus position into a quadratic function.

The DW curve may represent the level of total physical interaction as a function of changing the focus position of the laser light. The inflection point of the DW curve may be determined as the optimal focus position for the most accurate and sharpest pattern transcription at a desired location in the exposure process. Furthermore, by utilizing the DW curve when performing an actual exposure process, it may be possible to observe to what extent the focus of the laser light for forming each result varies from the reference optimum focus position, i.e., by performing an actual exposure process to form a pattern, collecting a pattern image, calculating a DW value from the collected pattern image, and comparing the DW value with the inflection point of the DW curve, it may be possible to observe to what extent the focus of the laser light may vary from the reference optimum focus position for any given pattern image. Thus, the DW curve may be utilized to track the accuracy of the laser focus position in the exposure process.

More specifically, in step S130, the pattern image may be divided into pixels to calculate the DW value of the pattern image. A pixel may mean the smallest unit into which the image may be divided. Next, the pixel histogram for the pattern image may be derived based on the brightness values of the segmented pixels.

For example, as shown in FIGS. 7A and 7B, one pattern image acquired at a random focus position may be divided horizontally and vertically into 512 pixels each. Then, a pixel histogram for the random pattern image may be generated. The generated pixel histogram may be any one of the pixel histograms of the focus positions shown in FIG. 8, for example.

By calculating the pixel histogram as described above, a pixel histogram scatter function for a corresponding pattern image may be derived and calculated as a DW value for a pattern image of the pattern to be analyzed. Accordingly, the DW value may mean an average brightness value, according to the plurality of pixels in a pixel histogram, that describes the variation of the pattern image of the pattern to be analyzed. After generating the DW value of the pattern image as described above, in a step described later, the DW value may be compared with reference focus information to determine whether an outlier has occurred.

Again, referring to FIG. 8, each pixel histogram may have a different curve shape because the pattern is formed at a different focus position. By calculating the pixel scatter from the pixel histograms generated for each pattern image, a scatter function of the different pixel histograms may be derived. In other words, the pattern image of the pattern formed by performing the exposure process at 11 different focus positions exhibits 11 different forms of histogram scatter as shown in FIG. 8.

In addition, while it may be important that the pattern be formed in the correct shape, it may also be important that the laser light may be concentrated in a single focal point so that the energy may be transferred well and the pattern may be deep and sharp.

Specifically, when the pattern is formed at the optimal focus position, the pattern image at the optimal focus position may produce precise and sharp patterns only where the patterning is intended. When the pattern is formed at a non-optimal focus, the energy of the laser light may be dispersed and the pattern may be shallow and blurred over a wide area beyond the intended location. Therefore, in the pattern image collected from a pattern formed in the non-optimal focus state, the brightness values distribution of pixels in an intended location may appear low compared to the pixel histogram generated from the pattern image in the optimal focus position, and the distribution of pixels at a position where the pattern might not be formed tends to relatively increase.

As a result, the DW curves generated from pattern images collected from patterns formed at non-optimal focus locations may tend to have low height and high scatter. The scatter may refer to the degree to which the pixel brightness values may be distributed.

The DW curve may have two different shapes. The DW curve may represent a quadratic function with a convex or concave shape. The DW curve may have different shapes resulting from the quadratic function depending on the difference between positive patterning and negative patterning.

In a positive patterning method, portions of the sub-patterns may be darkest in the pattern image collected by patterning at the optimal focus position because the pattern may be etched deepest at the optimal focus position. In other words, in the pattern image collected by forming a pattern at the optimal focus position using the positive patterning method, there may be a large distribution of dark colors and the x-axis of the histogram (pixel brightness) may be darker to the left, so the histogram of the pattern image collected by forming a pattern at the optimal focus position using the positive patterning method may be skewed or shifted to the left and have the smallest scatter.

In addition, in the positive patterning method, the pattern images collected at the focus position, where the degree of defocus gradually may increase from the optimum position, tend to show a tendency to have fewer and fewer sub-patterns etched in the pattern images collected as the distance from the optimum focus position increases. Therefore, the scatter of the pixel histogram may become greater and shapes to the right compared to the histogram at the optimum focus. Accordingly, when the DW curve is generated as the laser focus changes, it may appear as a convex quadratic function.

The pixel histogram calculated from the pattern image collected by forming a pattern using the above negative patterning method may exhibit characteristics opposite to those of the positive patterning case.

The pixel histogram of the pattern image may be constructed in accordance with the combination of the sub-patterns distributed in the pattern image and the pixels of the non-pattern background, and each pattern image collected when the pattern is transcribed at different focus positions may exhibit unique features. The features may be categorized into four types, including two types of positive patterning or negative patterning, and two types of whether the pixel histogram function may be right-skewed or left-skewed. This may be clearly seen through the scatter function of the pixel histogram.

In other words, the shape of the pixel histogram may represent a unique feature of the patterned image. When the pattern image is acquired while changing the focus of the laser, the shape of the DW curve may be convex or concave, which may be caused by the difference between positive and negative patterning. When transcribing patterns from a specific exposure process, the preset exposure process may be positive or negative. In addition, when performing the exposure process while changing the laser focus position, positive and negative patterning might not be mixed.

First, when performing a positive exposure process, the effect of molecular structure decay of the photoresist PR by the laser light may be greatest at the optimal focus position, resulting in a deep and clear pattern, so the number of dark pixels may theoretically be higher than in the image of a pattern transferred from a different focus position.

In contrast, as the defocus increases by moving further and further away from the optimal focus position, the number of dark pixels may tend to decrease due to the decreasing effect of molecular structure decay. As a result, pattern images taken at defocus positions and increasingly away from the optimal focus position have pixel histograms that gradually decrease in height and increase in scatter moving from left to right. Accordingly, a scatter function of the pixel histogram of the pattern image acquired by patterning with the positive patterning method at the defocus position may have the shape of a downward convex quadratic function with minimum scatter at the optimal focus position. On the other hand, in the process of patterning by negative patterning, the bonding between the laser light and the reacted photoresist molecules may be stronger. Therefore, when generating the pattern at the defocus position, the generated pattern image may have an increased number of dark-colored pixels due to the formation of an incomplete pattern due to the weak bonding. In this case, the shape of a pixel histogram calculated from the pattern image of the pattern generated at a defocused position of the laser in the negative patterning method may differ from the shape of the pixel histogram calculated in positive patterning in that the scattering becomes larger, and the height becomes lower and shapes to the left. Therefore, the scatter function of the pixel histogram may have the shape of an upwardly convex quadratic function. The pixel histogram calculated from the patterned image collected by forming a pattern using the negative patterning method may be mistaken as the optimal focus point with the largest scatter, but it should be noted that the focus position with the least amount of light-colored noise and the highest resolution and sharpest patterning may be preferred.

The description of the deformation of DW curves in accordance with the positive or negative patterning may be based on the simplest single pattern as an example, which may be fully consistent with a theoretical explanation, but when the pattern image is complex, different opposing tendencies may appear. Further reflection and development of rules and principles that may be generalized and applied to all complex patterns may be required.

For example, the change in the scatter of the pixel histogram due to the change in focus may be important, and the shape of the pixel histogram to the left or right might not be necessarily interpreted as being due to positive or negative patterning. Further, the shaping of the pixel histogram may optionally change the interpretation.

However, in the semiconductor exposure method of example embodiments, the shape of the pixel histogram in the left and right directions is not significant. This may be because example embodiments are based on the scatter of the pixel histogram, and when the scatter is the same when the pixel histogram is shaped to the left or the scatter is the same when the pixel histogram is shaped to the right, the DW curve may be the same. It can be noted that it may be easy to physically interpret the changes in the shape of the pixel histogram that occur in relatively simple patterns by utilizing the phenomena that occur during positive and negative patterning in example embodiments.

Also, for relatively complex patterns, it might not be possible to interpret the changes in the sub-patterns within the pattern image by comparing them individually, but at least the pixel histogram of the image shows the changes in all of the sub-patterns, so the DW curve may be useful in this way. Again, it may be important to note that regardless of the direction of movement of the pixel histogram, it may be the level of change in the scatter of the histogram, as the focus changes, that may be important.

In the semiconductor exposure method of example embodiments, in consideration of the characteristics described above, the optimal focus may be derived as shown in the graph as shown in FIG. 9 for all semiconductor patterns, for which it may be difficult to utilize conventional complementary curves, by measuring the scattering change of pixel histograms as the focus position changes.

In the step of determining whether an outlier may be generated in the pattern to be analyzed (S140), the DW value of the pattern image may be compared with the reference focus information to determine whether the laser light may be defocused and cause an outlier to occur in the pattern to be analyzed. When the outlier has been generated in the pattern to be analyzed, it may mean that the laser light may be defocused. The level of outlier generation may be determined using a plurality of pattern images with different focus positions. The level of the outlier may be determined in the following ways.

The reference focus information may include, respectively, a reference pattern image for the pattern formed at the optimal focus position, a reference DW value of the reference pattern image, and an upper limit DW value and a lower limit DW value set based on the reference DW value.

In step S140, a DW value of a pattern image may be compared with the reference focus information, and when the DW value of the pattern image exceeds the upper limit DW value of the reference focus information, or when the DW value of the pattern image falls below the lower limit DW value of the reference focus information, it may be determined that an outlier in the focus of the laser light has occurred.

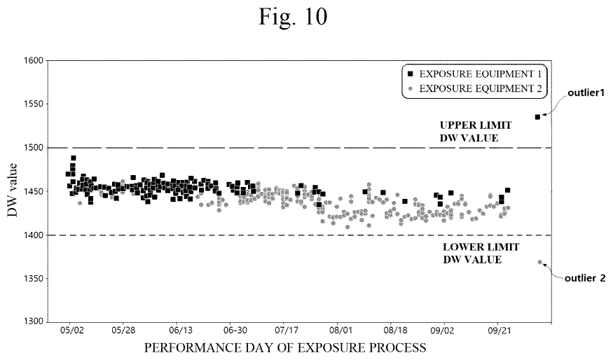

FIG. 10 is a graph illustrating DW values for each day of an exposure process. FIG. 10 results from repeatedly performing an exposure process utilizing two different semiconductor exposure equipment to form a pattern on a wafer in accordance with example embodiments on different days, and monitoring DW values by collecting pattern images on each day of the exposure process.

Referring to FIG. 10, it may be seen that DW values may fluctuate within a certain range when the semiconductor exposure process is repeatedly performed, as may be seen from the DW values for each day of the exposure process of the semiconductor exposure equipment. Similarly, when forming a pattern repeatedly, the DW value may fluctuate even when forming the same type of pattern under the same conditions. When the DW value exceeds the upper limit DW value or fall below the lower limit DW value in a specific exposure process, it may be determined that an outlier has be generated by the exposure equipment. The DW value monitoring result shown in FIG. 10 may be only an example, and the DW value monitoring result may differ depending on the type, shape, exposure equipment, exposure conditions, etc. of the pattern. For example, the reference pattern image of the pattern with the monitoring result as shown in FIG. 10 may have a reference DW value of 1450, and an upper limit DW value and a lower limit DW value may be calculated based on the reference DW value. The reference DW value may be only an example, and the reference DW value may vary depending on the pattern and patterning conditions.

As mentioned above, when the outlier is confirmed to have occurred on a specific exposure process date, a notification signal may be generated to notify the user that the outlier has occurred in the semiconductor exposure equipment.

The reference focus information may include a reference DW value. The reference DW value may be derived by calculating the pixel histogram from the pattern image of the pattern generated at the optimal focus position. The reference focus information may be derived by forming a pattern having the same shape and critical dimension scale as the pattern under analysis, but at the optimal focus position, and then calculating the pixel histogram from the pattern image of the pattern generated at the optimal focus position.

The upper DW value and the lower DW value may be calculated based on the reference DW value. The upper DW value and the lower DW value may represent boundaries of suitable focus locations that result in acceptable sharpness and pattern shapes. The upper DW value and lower DW value may be arbitrarily changed at the user's option depending on the size and threshold dimensions of the pattern.

When the exposure process is performed at a conformal focus position or an optimal focus position, a pattern may be formed at a precise location on the wafer, and the pattern image of the pattern may be characterized by a deep, clear, and noise-free pattern. When the exposure process is performed at the defocus position, the pattern image of the pattern may be characterized by a pattern formed at a relatively inaccurate position, or a relatively shallow and blurry pattern is identified in the pattern image. The DW value calculated from a pattern image of the pattern formed at the optimum focus position may exhibit a characteristic of being located between the upper limit DW value and the lower limit DW value. The DW value calculated from a pattern image of the pattern formed at the optimal focus position may represent a characteristic located in the center region of the upper and lower DW values. The DW value calculated from a pattern image of the pattern formed at the defocus position may represent a characteristic that lies in the region above the upper DW value or below the lower DW value.

In other words, the reference focus information may be calculated using the pattern image collected from the pattern formed by irradiating laser light at the optimal focus position.

The method of disclosed embodiments includes repeatedly forming the pattern on the wafer using the light source at a plurality of focus positions using the semiconductor exposure equipment; collecting focus position-specific pattern images for the pattern formed at the plurality of focus positions and deriving pixel histograms of the focus position-specific pattern images, respectively; extracting the pattern image of the pattern formed at the optimal focus position of the light source using the pixel histograms of the pattern images by focus position, and selecting the extracted pattern image as the reference pattern image; deriving the reference DW value of the reference pattern image; and setting an upper DW value and the lower DW value using the reference DW value according to a preset criterion.

More specifically, the reference focus information, when forming the pattern with the same shape and critical dimension, is used to adjust the focus position to collect the pattern image for each focus position. Then, the pixel histogram of the collected pattern image may be used to calculate the brightness value of the pixels and the number of pixels per brightness value. When forming the pattern on the wafer including a plurality of sub-patterns, which have at least one of a shape and a critical dimension different from each other, the reference focus information may be calculated by weighted averaging the distribution level of the number of pixels per brightness value over the plurality of sub-patterns, using the pixel histograms for all of the plurality of sub-patterns included in the pattern.

In example embodiments, the semiconductor exposure method may detect an outlier generation level of the pattern to be analyzed.

According to example embodiments, the step of determining whether the outlier has occurred in the pattern may further include detecting a level of outlier generation of the pattern to be analyzed by comparing the similarity of the pattern image and a reference pattern image. The step of detecting the level of outlier generation of the pattern to be analyzed may be performed when the outlier has occurred in the pattern to be analyzed.

Specifically, in the step of detecting the level of outlier, a reference pattern image or a pre-outlier pattern image collected by performing an exposure process at an optimal focus position may be collected. Then, a similarity comparison may be performed between the reference pattern image or the pre-outlier pattern image and a post-outlier image or the pattern image determined to be anomalous, and a determination may be made that an area on the pattern image is anomalous.

By using a vector similarity-based method, the pattern image may be quantized into a single vector to detect the level of outlier based on the similarity of the size and orientation of the vectors.

The vector similarity-based method may be used for comparing similarities of pixel histograms. The vector similarity-based method may include, for example, cross correlation distance, chi-square distance, intersection distance, Bhattacharyya distance, and cosine distance. The pixel histogram generated from the pattern image may be a visualization of the degree distribution table. In the pixel histogram, the horizontal axis may represent rank and the vertical axis represents number of degrees.

The pixel histogram of the pattern image of the pattern to be analyzed may be compared with the pixel histogram of the reference pattern image or the pre-outlier pattern image collected by performing the exposure process at the optimal focus position, and a vector for the pattern image of the pattern to be analyzed may be calculated.

More specifically, the cross-correlation distance may measure how similar the distributions of two histograms are via their inner product. The cross-correlation distance may have a value of 1 when the two histograms are completely consistent, −1 when they are completely inconsistent, and 0 when they are not correlated. In other words, the closer the cross-correlation distance is to 1, the more similar the two-pixel histograms are, and the closer it is to −1, the more different the distributions of the two-pixel histograms are.

The chi-square distance may be a method of measuring the likelihood of a new pixel histogram distribution appearing with respect to a reference pixel histogram among two-pixel histograms. The chi-square distance may have a value of 0 to ∞, with values closer to 0 the more similar the two distributions are. In other words, the chi-square distance may indicate how similar the pixel histogram vector calculated based on the reference pixel histogram vector is among the two-pixel histograms. Therefore, the closer the chi-square distance is to 0, the more similar the two-pixel histograms are, and the further away from 0 the value is, the more different the distribution of the two-pixel histograms is.

The intersection distance may be a method for calculating a width over which the two-pixel histograms overlap. The intersection distance may have a value of 0 to 1, and the more similar the distributions of the two-pixel histograms are, the closer the value is to 1. In other words, the closer the intersection distance is to 1, the more similar the two-pixel histograms are, and the closer the value is to 0, the more different the distributions of the two-pixel histograms are.

The Bhattacharyya distance may be a method for measuring the similarity of a distance to a probability distribution of two-pixel histogram vectors. The distribution similarity of the pixel histogram vectors may be calculated by dividing the two-pixel histogram vectors by the total size of the histogram so that the sum may be a probability distribution of 1. It may be calculated by utilizing an expression in the form of adding the sizes of the areas where bins of the two histogram vectors overlap and then subtracting 1 from the added value. The closer the value is to 1, the smaller the overlap, and the closer the value is to 0, the larger the overlap, indicating that the data of the two-pixel histogram vectors are similar.

The cosine distance may be a method for detecting similarity by dividing the inner product of two-pixel histogram vectors by the product of two-pixel histogram magnitudes. The cosine distance may have an interval value of −1 to 1, with a value closer to 1 the more similar the two-pixel histogram vectors are, a value of −1 when they are completely dissimilar, and a value of 0 when they are not related. In other words, the closer the cosine distance is to 1, the more similar the two-pixel histograms, and the closer the distance is to −1, the more dissimilar the distribution of the two-pixel histograms.

The vector similarity-based method may be utilized to quantize the pattern image into a single vector. In other words, the vector similarity-based method as described above may be used to calculate the vector similarity of the calculated pixel histogram to the reference pixel histogram vector in order to calculate anomalies and determine the level of outlier generation. In this step, the magnitude and cosine angle of the vector may be compared. When the magnitudes and cosine angles of the vectors are found to be completely identical, the pattern images may be determined to be the same image. The vector similarity-based method as described above may quantify and compare the similarity between the reference pixel histogram and the pixel histogram within a short period of time and with a small amount of resources. Therefore, in this manner, an outlier level may be derived from the similarity comparisons described above.

It may be possible to derive not only the level of outlier but also the location of the outlier. However, it may be difficult to determine the location of anomalies in a two-dimensional pattern image using only the vector similarity-based method above.

Accordingly, structural similarity between the image vector of the transformed pattern and the transformed vector of the reference pattern image is evaluated, and an outlier location of the pattern to be analyzed may be detected. The outlier location may be derived from the two-dimensional pattern image by utilizing an SSIM technique, which may segment the pattern image to be analyzed into local regions and compare the local similarity with the reference pattern image.

The SSIM technique may evaluate the similarity of the reference pattern image and the pattern image to be analyzed by considering three factors, such as the structure of the pattern image, the brightness of the pattern image, and the contrast of the pattern image. The SSIM method may evaluate the similarity of the pattern images by comparing the structural characteristics of the pattern images, rather than simply the difference in pixel values in the pattern images, by simulating the way the human system recognizes images. The SSIM technique evaluates whether the pattern images are similar in texture, structural brightness, etc. and focuses on determining how similar the pattern images look rather than just color accuracy, so it may precisely evaluate the qualitative aspects of the images to calculate the location of the outlier.

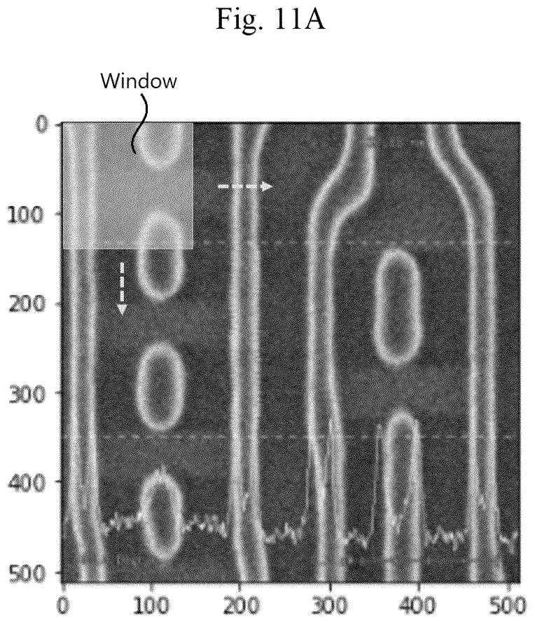

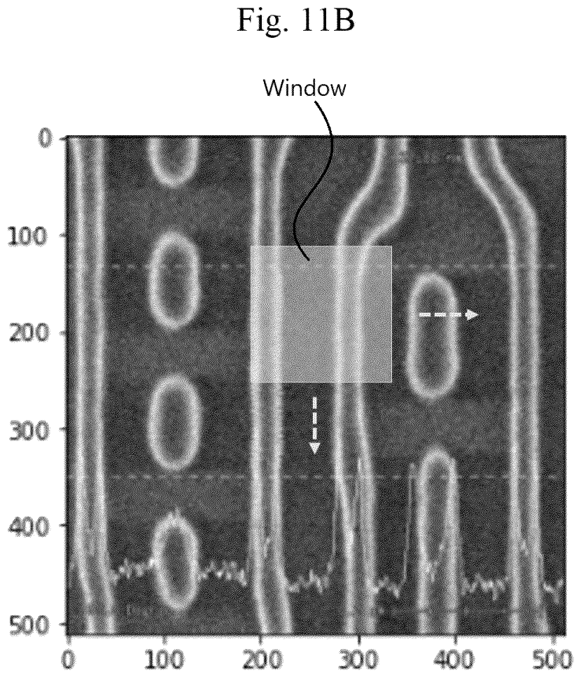

FIG. 11A is a flow chart illustrating a creation of a window in a pattern image of a pattern to be analyzed, in accordance embodiments of the disclosure. FIG. 11B illustrates a window created in a pattern image of a pattern to be analyzed using an SSIM technique for comparison, in accordance with embodiments of the disclosure.

As shown in FIG. 11A, a window may be generated on a pattern image of a pattern to be analyzed. Then, the similarity between a reference pattern image and the pattern image of the pattern to be analyzed is evaluated by moving the generated window over the pattern image, as shown in FIG. 11B. In FIGS. 11A and 11B, the window may be generated only on the pattern image of the pattern to be analyzed, but in an SSIM technique, the window may also be formed on the reference pattern image at the same position as on pattern image of the pattern to be analyzed, so that the same regions may be compared between the reference pattern image and the subject pattern image.

Utilizing the method described above, the pattern image of the pattern to be analyzed may be evaluated as to whether the texture, structure brightness, etc., of the pattern image is similar to the reference pattern image. Accordingly, an outlier location may be derived from the pattern image of the pattern to be analyzed.

In semiconductor exposure methods in accordance with example embodiments, the level of outlier generation may be derived as described above, and the location of outlier generation may be derived from the pattern image of the pattern to be analyzed, thereby providing a reliable analysis result, to a process manager, regarding the focus position of a laser light in a semiconductor patterning process resulting in an outlier.

In addition, the outlier level of the pattern under analysis may also be detected by the following methods.

A plurality of focus positions may be selected by dividing the separation distance between the laser light source and the lens into a plurality of focus positions. The focus positions may be divided according to a preset criterion. Then, a patterning process may be performed at each of the selected plurality of focus positions to form a pattern for each focus position. Next, pattern images may be collected for each of the formed patterns. In the collected pattern images, the patterns having different characteristics for each focus position may be identified. For example, a pattern image of the pattern to be analyzed formed when the laser light is defocused may have a lower clarity and shallower depth than a pattern image formed at the optimal focus position. Also, the formed pattern may have an inaccurate formation position.

More specifically, referring to FIG. 7A, the best pattern image for a pattern formed at the optimal focus position may show the pattern formed at the most accurate location, and the pattern image may show the sharpest and deepest pattern.

Referring to FIG. 7B, in the pattern image of the pattern formed at a defocus position that may be excessively distant from the optimal focus position above, the pattern may be lost or have low pattern clarity and shallow depth.

Such characteristics of pattern images may indicate a tendency for defocus positions to increase in proportion to the distance from the optimal focus position.

For example, when the DW value of a pattern image of the pattern formed at a focus position that is separated from the optimal focus position by a certain distance, and the DW value of the pattern image is between the optimal DW value and the lower limit DW value, the pattern image may be confirmed to have a suitable shape and threshold scale, even though the sharpness and depth may be relatively reduced compared to a pattern image at the optimal focus position.

However, when a pattern is formed at a defocus position, the pattern image may have a DW value that exceeds the upper DW value or falls short of the lower DW value. By comparing the DW value of the analyzed pattern image with the reference DW value, the deviation between the DW value of the calculated image and the reference DW may be checked, and as the deviation increases, the level of outlier increases.

While evaluation for an outlier generation level described above occurs when an outlier has occurred, embodiments are not limited to analysis after an outlier has occurred. In other embodiments, the methods used to evaluate outlier generation level may also applied when the DW value falls between the upper DW value and the reference DW value, or between the lower DW value and the reference DW value.

More specifically, when the DW value calculated from a pattern image is determined to be between the upper DW value and the reference DW value or between the lower DW value and the reference DW value, the defocus degree may be relatively low depending on the deviation. On the other hand, when the DW value calculated from the pattern image may be detected in an area beyond the upper DW value or the lower DW value, the degree of defocus is larger, and it is possible to detect the level of outlier.

When the DW value is calculated during the process of repeatedly forming a multi-session exposure process and collecting pattern images, and the calculated DW value exceeds the upper DW value or is confirmed to be below the lower DW value, the time at which an abnormal pattern image is formed may be found by checking the corresponding pattern image.

Again, referring to FIG. 10, when a semiconductor exposure process is repeatedly performed, the DW value fluctuates by the performance day of the exposure process. When the DW value exceeds the upper limit DW value or falls short of the lower limit DW value in a specific exposure process, the time at which an outlier occurs and the exposure equipment may be identified by checking the date of the exposure process.

Determining whether an outlier has occurred in a pattern to be analyzed may further comprise, when the laser light is defocused and it is determined that an outlier has occurred in the pattern to be analyzed, determining a factor most responsible for generating the outlier. In the exposure process, a plurality of outlier generators may be involved in generating the outlier. A dominant outlier contributing factor means the most dominant outlier contributing factor among the plurality of outlier contributing factors that contribute to the outlier in the exposure process.

A machine learning model for predicting the generation of anomalies by semiconductor exposure equipment may be based on the process and equipment conditions for performing the exposure process and the resulting DW values.

For example, a machine learning model may predict outlier generation time and outlier generation level based on the process and equipment conditions for performing the exposure process, and the direction of change, trend of change, and rate of change of the DW value. The time of generation of the outlier may be calculated by deriving a trend direction and a trend angle of the DW value from the change of the DW value over time, and the level of generation of the outlier may be calculated by using the trend angle.

The machine learning model may select anomalies related to the exposure equipment and the exposure process that are expected to have a larger impact on the change of the DW value. The larger impact on the change of the DW value is determined by considering the correlation with the trend direction and trend angle of the DW value when utilizing multiple exposure equipment or performing multiple exposure processes. And the machine learning model may provide a result of the improvement level of the changed DW value by controlling the selected anomalies through simulation. Machine learning models will be described in more detail below.

An outlier factor may be an exposure process condition, a driving condition of the exposure equipment, and the like. For example, outlier factors may include a focus position of the laser light, an energy level of the laser light, a breakage of a laser light source and a lens installed in the semiconductor exposure equipment, an incident angle of the laser light and the lens, a contamination of the laser light source and the lens, a result of a wafer processing process performed prior to the exposure process, a vibration of the exposure equipment, and other conditions of the exposure process. The anomalies may be caused by any one of the anomalies, or may be caused by a plurality of the anomalies.

The machine learning model may be used to derive key outlier generation factors that have a major impact on outlier generation from a pattern image of the pattern under analysis. The key outlier factors may be derived in the following ways.

A major outlier generating factor may be derived by a method including the steps for extracting outlier features from a pattern image of a pattern to be analyzed and deriving the major outlier generating factor from the outlier features extracted using a machine learning model.

For example, in the outlier feature extraction step, outlier features may be extracted from pattern images that are determined to be outliers. The outlier features may be extracted by utilizing a feature extraction filter. The feature extraction filter may be configured to extract features related to pixel values (color), amount of light energy (illumination), noise, and pattern shape from a pattern image of a pattern to be analyzed in comparison with a reference pattern image.

More specifically, the feature extraction filter may extract pixel values, illumination, and pattern shapes of a region of the pattern image to be analyzed. The feature extraction filter is utilized to better extract features of anomalies occurring by outlier type. The feature extraction filter may compare a reference pattern image and the pattern image to be analyzed, and extract pixel values, illumination, and pattern shapes that are different as outlier features. The types of extracted anomalies may differ from each other depending on the type of outlier causing factor.

The feature extraction filter may compare the reference pattern image and the pattern image to be analyzed to extract anomalous features such as pixel values, illumination, and pattern shape.

Next, key outlier factors may be derived from the above outlier features extracted using the machine learning model in a step of deriving key outlier factors.

The contribution of each factor to the outlier in the machine learning model may be based on the degree to which changes in each of the multiple outlier factors (x-axis values) affect changes in the resulting factor, DW (y-axis).

When any of the above outlier factors fluctuate, the DW value on the Y-axis is affected and fluctuates, and the level of fluctuation of the DW value due to the fluctuation of the above outlier factors may be called correlation. When the outlier generation factor with a large correlation changes to a large value, the DW value will fluctuate in a larger range. On the other hand, when the correlation is small, the DW value will fluctuate in a smaller range even when the correlation is large. Using such correlation, the machine learning model may detect anomalies that cause the DW value of the pattern image to fluctuate significantly at a level that is judged to be anomalous, and present the likelihood of the anomalies can be organized in priority order.

A machine learning model is not derived using only one outlier and its correlation with the DW value. Instead, a machine learning model must take into account noisy issues such as multicollinearity, where multiple anomalies may be highly correlated with each other and the anomalies interact with each other. The machine learning model may use mining techniques to prioritize the anomalies and derive key anomalies. The machine learning model may learn big data to derive the contribution of the outlier causing factors by feature, and provide reliable results on the cause of the outlier based on the contribution of each feature (Feature Importance).

After the machine learning model is built, another portion of the model is separately built for collecting a pattern image of a pattern determined to be abnormally generated and collecting abnormal generation type information from the collected pattern image. Then, a plurality of abnormal generation factors associated with the abnormal generation type are learned using the machine learning model, and the machine learning model learns big data to derive the contribution of the abnormal generation factors according to the factor. The machine learning model may evaluate the analysis algorithm based on the feature importance to provide reliable results on the cause of the outlier. For the object of analysis that is determined by the machine learning model as having an outlier, the time of the outlier, the level of the outlier, and the main causative factor may be presented according to the contribution of the feature importance, and in order to analyze and learn the exact outlier site and characteristics, the pattern image of the pattern may be collected and a local site compared with existing normal pattern images. Coordinates and the level of the outlier at the local site may be learned and stored separately from the machine learning model. Alternatively, the performance of the model may be enhanced so that the machine learning model may inspect the same local site in subsequent pattern images first for abnormalities. The machine learning model obtains data including all measurable process and equipment factors in the exposure process. The machine learning model excludes anomalous factors that are clearly not affecting the change of the dependent variable DW value (Y-axis value) from the model construction to increase the robustness and accuracy of the model. The machine learning model may repeat the above exclusion process to learn a dataset consisting of the final selected outlier factors and the DW values of the pattern images. When predicting the generation of an outlier, the machine learning model may utilize an analysis algorithm to select the machine learning model with the best fit (correlation with data, explanatory power). The machine learning model may refer to the process of building a model by applying machine learning methods to data corresponding to 70 to 80 percent of the total data set. After the machine learning model has been built through training as described above, the performance of the machine learning model may be improved by repeating the process of evaluating and rebuilding the model by inputting the remaining about 20% to about 30% of the test data set to the training model.

A combination of methods to evaluate the performance of the model, such as Mean Squared Error (MSE), Root Mean Squared Error (RMSE), and others may be evaluated to select the best performing metric.

These more robust and reliable machine learning models enable management and prediction of when and how much DW value anomalies occur, and reliable tracking of the causes of these anomalies.

Furthermore, the analysis algorithms may utilize at least one of Linear Regression, Lasso, Ridge, Decision Tree, Random Forest, Gradient Boost, LGBM, Light GBM, and XGB, and XG Boost.

The performance of the machine learning model may be tested by comparing the predicted DW values (Y-axis values) with the DW values (Y-axis values) in the actual data set of patterned images. The various variables present in the equations of each learning model are called hyper parameters, and by tuning the hyper parameters, a machine learning model with an optimal function that may best describe the data set may be derived. At this stage, the derivation of the learning model as described above may be only a description of the method and principle of building a machine learning model, and the types, principles, and formulas of each learning model may vary. Accordingly, features such as the construction process of the learning model, analysis performance according to the amount of data, analysis time, etc. also vary. The learning models may be selectively utilized as needed, and may also be configured to continuously change to reflect external conditions.

Further, the machine learning model may be configured to use a pattern image to derive key outlier causing factors, and then generate and provide to an administrator simulation information to predict the level of change of the key outlier causing factors to reduce the generation of anomalies, and the results of patterning by the level of change of the key outlier causing factors.

Further, the machine learning model may predict when a particular semiconductor exposure machine will experience an outlier during the course of performing an exposure process using a plurality of semiconductor exposure machines.

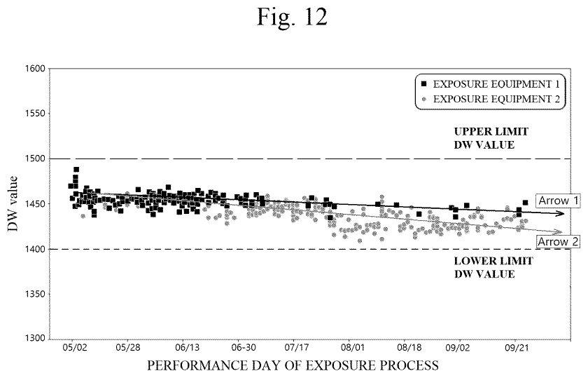

FIG. 12 shows results of repeatedly performing an exposure process to form a pattern on a wafer utilizing different semiconductor exposure equipment in accordance with embodiments of the disclosure.

Referring to FIG. 12, an exposure process is repeatedly performed using semiconductor exposure equipment, and DW values fluctuate depending on the date of the exposure process. The fluctuation of the DW value may indicate a trend. By utilizing the trend, it may be possible to predict when an outlier will occur for the corresponding semiconductor exposure equipment.

For example, a semiconductor exposure equipment 1 may have an initial DW value that exceeds the reference DW value, and the DW value has a trend of gradually decreasing during repeat exposure processes. Therefore, it may be possible to predict when the lower limit DW value is reached by calculating the slope (Arrow 1) for the average value of the DW value by the date of the exposure process using semiconductor exposure equipment 1.

In addition, semiconductor exposure equipment 2 may have an initial DW value similar to the reference DW value, but exhibits a trend of decreasing DW value during repeated exposure processes. The slope (Arrow 2) of the average value of the DW value for each day of the exposure process using exposure equipment 2 is lower than the slope (Arrow 1) for the exposure equipment 1, and the point at which the lower limit DW value is reached using exposure equipment 2 may be earlier than that of exposure equipment 1 when the exposure process is repeated over the same period time.

The machine learning model may predict when an outlier of a specific semiconductor exposure equipment occurs by checking the DW value trend of the semiconductor exposure equipment during the process of performing an exposure process using a plurality of semiconductor exposure equipment.

Further, a simulation function that detects a major outlier generating factor and then suggests a level of improvement required to control process variables of the semiconductor exposure process associated with the major outlier generating factor may be used to determine whether an outlier has occurred in the pattern. The simulation function may be configured for direct automatic control. The major outlier generating factors may be presented in priority order among a plurality of outlier generating factors using correlation to the factor's impact on outlier generation.

Controlling process variables of a semiconductor exposure process may further include generating and providing patterning prediction information based on DW values derived from controlling process variables of the semiconductor exposure equipment associated with the major outlier generation factors to form a pattern on the wafer with semiconductor exposure equipment.

Determining whether an outlier has occurred in the pattern to be analyzed may further include performing a history management of DW values and outlier factors by exposure process in the semiconductor exposure equipment, comparing and analyzing differences between outlier factors and outlier levels, and outputting and providing an improvement method for improving the outlier.

The foregoing description has described formation of a pattern including one sub-pattern SP1 as an example, but referring again to FIG. 7A, the semiconductor exposure methods in accordance with example embodiments may also be utilized to form a pattern comprising a plurality of sub-patterns.

The pattern may have a structure including a plurality of sub-patterns (SP1 to SP5) having different shapes and sizes. Specifically, the sub-patterns SP1 to SP5 may be patterns that are small enough to form the pattern identified in the pattern image. In other words, the pattern may be a pattern set including a plurality of sub-patterns SP1 to SP5.

More specifically, in one example, formation of the pattern may comprise forming a pattern set on a wafer including a plurality of sub-patterns SP1 to SP5 that differ in at least one of shape and threshold size in a single photolithography process.

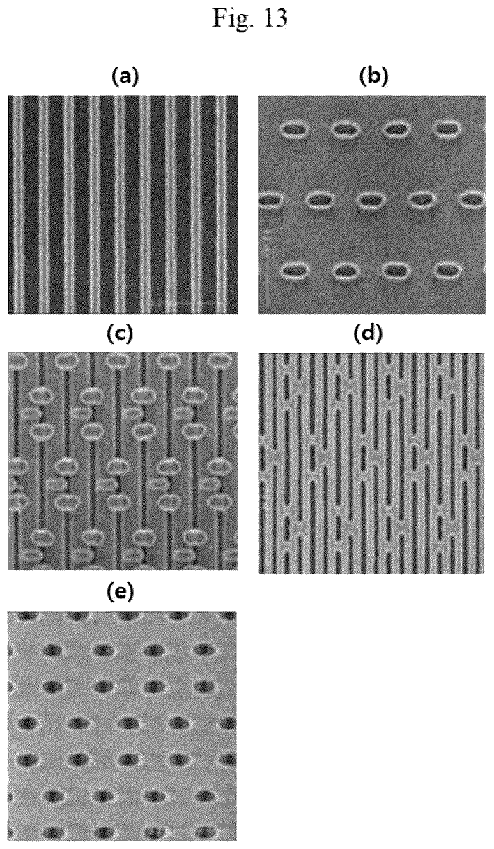

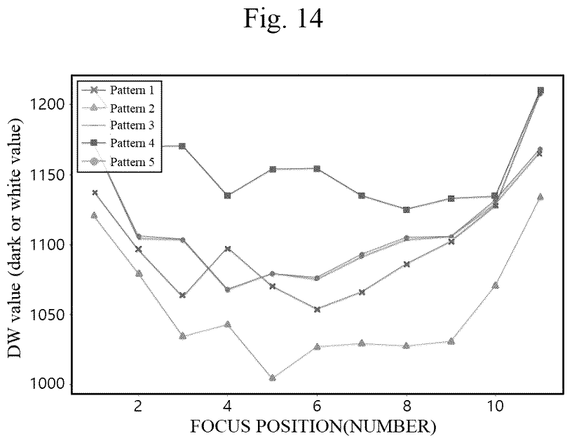

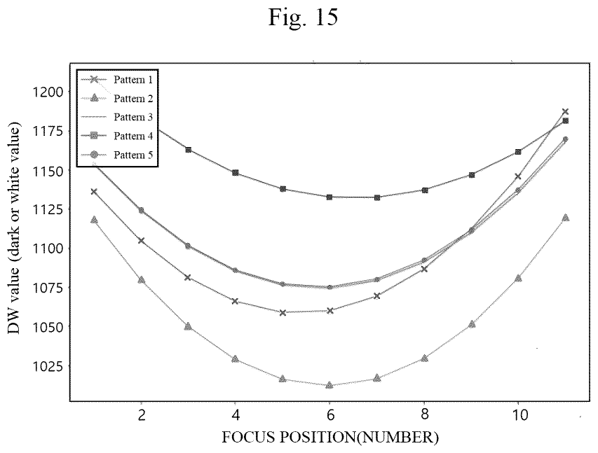

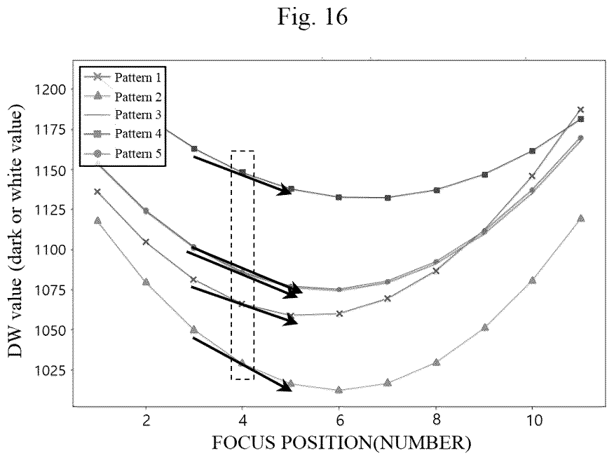

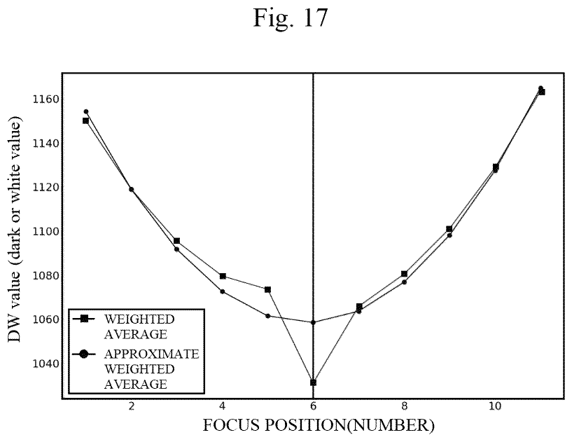

FIG. 13 is a pattern image collected from five patterns with different shapes and thresholds in accordance with embodiments of the disclosure. FIG. 14 is a focus graph generated by forming each of the five patterns of FIG. 13 with different shapes and thresholds at each of the eleven focus locations and then deriving a histogram scatter function for each of the five sub-patterns in accordance with embodiments of the disclosure. FIG. 15 is an approximation-corrected graph of the focus-by-focus graph of FIG. 14. FIG. 16 illustrates a derivative of the approximate calibration graph in FIG. 15 at an arbitrary focus position. FIG. 17 is a focus graph and its approximation correction graph for a pattern set comprising the five patterns as a whole, calculated by weighted averaging the derivatives of FIG. 15.

Referring to FIGS. 13 to 17, a plurality of pattern image-specific pixel histogram scatter functions for first to fifth patterns, which are plotted in a single plot, may be derived for each of the first to fifth patterns having different shapes and threshold dimensions at a total of eleven focus positions.

Then, the DW values of the plurality of pattern images for the first to fifth patterns, i.e., the pixel histogram scatter function, may be used to generate a focus graph for a first pattern. Then, this focus graph generation may be repeated for the remaining patterns to generate multiple focus graphs for the plurality of patterns and plotted in a single plot.

In addition, approximation processing may be performed on each of the plurality of focus graphs to generate a plurality of approximation processing graphs for each of the first to fifth patterns.

From the focus positions and DW values of all the approximated pattern images, the derivative of the slope of the pattern-specific function at each focus position (x-value) is derived. In this way, the amount of change in the individual pixel histogram scatter (y-axis) as the specific focus position (x-value) changes.

The derivatives of the first to fifth patterns may then be used to generate an overall focus graph for the plurality of patterns that takes into account the pattern-specific weights of all patterns. Then, the overall focus graphs may be weighted averaged to generate a single overall weighted average graph for all of the plurality of patterns. The overall approximate weighted average graph may then be used to calculate an optimal focus position considering all of the plurality of patterns. The optimal focus position considering all of the plurality of patterns may be an inflection point of the global approximate weighted average graph.

In other words, the slopes of the focus and DW values of all patterns by focus position (x-value) are calculated and then a weighted average of the slopes is calculated. The weighted average value allows the pattern image with the largest change to be prioritized when the focus changes. The weighted average value may also display the total change level of all patterns due to the change in focus position.

Then, for each focus position (x-value), the weighted average value of all the first to fifth patterns may be calculated, and the DW value (y-axis) based on the weighted average value of the focus (x-axis) and all sub-patterns (SP1 to SP5) may be expressed as the inflection point of the function. In this way, the optimal focus position of the laser light may be derived considering multiple patterns.

Then, as shown in FIG. 17, the derivatives of all the derived patterns may be used to derive the weighted average final focus and DW values considering the pattern-specific weights of all the sub-patterns. Based on the weighted average result as described above, the inflection point may be identified to calculate the optimal focus position for all patterns when multiple patterns are formed in a single photolithography process.

Furthermore, at this stage, the above methods may be utilized to establish a unified mathematical/scientific logic for objectively analyzing the focus impact of each pattern, which refers to the level of change in the physical interaction of the pattern as a result of the change in focus, regardless of the shape of the pattern.

Furthermore, in the laser light source, the proper focus is formed at a very fine size of a few nanometers (nm) to a few micrometers (μm). The laser light source may be sensitive enough to be easily defocused when vibration or the like occurs in the installed equipment. Accordingly, since it is difficult to transfer the pattern at a single location that may be the optimal focus of the laser light in all processes, it may be possible to calculate an error margin for changes in the focus position that may minimize external influences on the pattern transfer. Furthermore, techniques may be needed to monitor the focus position to ensure that the focus position may be maintained with an acceptable tolerance. Accordingly, in an embodiment of the patterning management method, the approximation correction results may be utilized to calculate an error margin for focus changes that may minimize external influences on pattern transcription. The error range may be calculated by checking the approximation correction result to confirm the change in pattern shape due to the focus change, and calculating the error range when the level of change in the DW value (y-axis) remains at a preset level.

The level of change of the DW value (y-axis) may be calculated as a margin of error between 0 and 10% or less, or another value other than that may be selected and calculated as a margin of error.

The DW value may also provide a quantitative indication of how much the defocused pattern image deviates from the optimal focus position compared to the most ideal pattern image formed at optimal focus.

The deviation of the optimal focus position from the defocus position as described above, i.e., a quantitative number, may be calculated using the DW value for each pattern image. The DW value may be calculated using the number of pixels per pixel brightness value.

Accordingly, the defocused location may be quantitatively identified by calculating the difference between the pixel brightness value and the pixel count in the pattern image of the best focus location and the pattern image of the worst focus location, dividing the calculated difference values by the number of focus locations to calculate the unit deviation value, and then comparing the pixel brightness value and the pixel count of the pattern image of the best focus location and the unknown focus location, and applying the unit deviation value. Alternatively, methods other than those described may be utilized.

Furthermore, in the semiconductor industry, there are currently no measures or methods to determine at what level of focus the laser used to produce a particular product may be produced. However, by utilizing the semiconductor exposure method according to an embodiment, the focus level of the laser used in the production of a particular product may be accurately determined from the pattern image. In other words, when laser light is irradiated at an optimal focus, the exact location where the laser light is concentrated may be known, so that the micro-pattern may be accurately and clearly transferred to the desired location.

It should be noted that the plurality of pattern images shown in FIG. 13 is merely an example to represent CD-SEM images of patterns, and the plurality of pattern images might not have been used to produce the results of FIGS. 14 through 16.

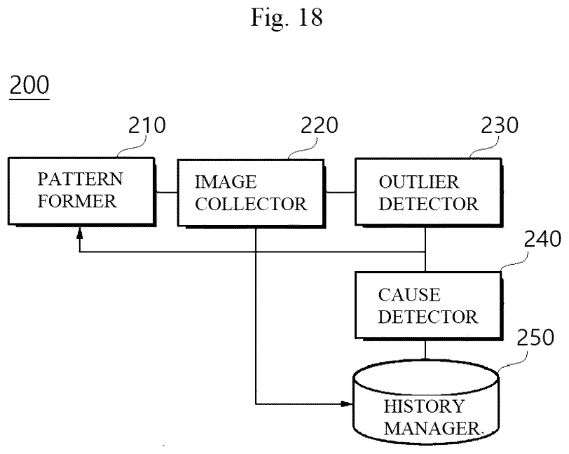

FIG. 18 is a block diagram illustrating a semiconductor exposure system in accordance with embodiments of the disclosure.

Referring to FIG. 18, a semiconductor exposure system 200 may have a structure including a pattern former 210, an image collector 220, and an outlier detector 230.

The pattern former 210 may serve to form a pattern on the wafer by performing a photolithography process using the laser light.

The pattern former 210 may be implemented using semiconductor exposure equipment having various conventional forms utilized to form patterns on wafers via a photolithography process, including use of a laser light source. For example, referring to FIG. 6, the pattern former 210 may have a structure including a laser light source 211 for generating laser light, lenses 212 and 212′ for focusing the laser light, a mask 213 on which the transfer pattern is formed, and a stage 214 configured to form a structure on which the wafer W is mounted and movable.

The laser light source 211 may include at least one of a KrF excimer laser light source, an ArF excimer laser light source, an ArFi laser light source, and an EUV laser light source.

At least one lens 212 and 212′ may be installed in the pattern former 210 as needed. Although the drawings illustrate semiconductor exposure equipment having a structure with two lenses installed, the semiconductor exposure equipment is not limited to such a structure in other embodiments.

The pattern former 210 may form a structure for selectively adjusting the focus position. The pattern former 210 may form a pattern on the wafer at each focus position.

Further, the pattern former 210 may include a plurality of semiconductor exposure equipment. The plurality of semiconductor exposure equipment may have different manufacturers, different patterning conditions, etc. The plurality of semiconductor exposure equipment may each independently perform an exposure process to simultaneously form a plurality of patterns having the same characteristics.

The image collector 220 serves to collect a pattern image of the pattern to be analyzed. The image collector 220 may collect the pattern image of the pattern to be analyzed using various types of devices conventionally utilized for photographing patterns in an exposure process for manufacturing semiconductor devices.

In one example, the image collector 220 may include a critical dimension scanning electron microscope (CD-SEM) device, and may acquire CD-SEM pattern images.

The image collector 220 may collect pattern images for the patterns formed by the pattern former 210. When at least one of the plurality of patterns formed by the pattern former 210 is designated as a pattern to be analyzed, the image collector 220 may collect a pattern image for the pattern to be analyzed and transmit the collected pattern image to the outlier detector 230.

The outlier detector 230 receives the pattern image collected by the image collector 220. The outlier detector 230 segments the pattern image collected by the image collector 220 on a pixel-by-pixel basis. The outlier detector 230 may calculate a pixel histogram representing the degree of dispersion of the pixel values from the collected pattern image, and the outlier detector 230 derives a pixel histogram scatter that statistically represents the brightness at each pixel position, and calculates a DW value of the collected pattern image. The outlier detector 230 may compare the DW value of the pattern image calculated with the reference focus information to determine whether an outlier occurs in the focus of the laser light. The reference focus information may include a reference pattern image for a pattern formed at an optimal focus position, a reference DW value of the reference pattern image, and an upper limit DW value and a lower limit DW value set based on the reference DW value, respectively.

The outlier detector 230 compares the DW value calculated from the pattern image of the pattern to be analyzed with the upper DW value and the lower DW value. When the DW value of the pattern image to be analyzed exceeds the upper limit DW value, or when the DW value of the pattern image to be analyzed falls below the lower limit DW value, the outlier detector 230 may determine that the pattern is abnormal due to a deviation of the focus position in the exposure process.

The outlier detector 230 may select the upper DW value and the lower DW value based on the reference DW value. The outlier detector 230 may select the upper DW value and the lower DW value according to the preset criteria. The outlier detector 230 may vary the upper DW value and the lower DW value as needed.

The outlier detector 230 may generate reference focus information. The reference focus information may be generated by collecting a pattern image of a pattern generated at the optimal focus position.

The outlier detector 230 may calculate the reference focus information in the following way. The semiconductor exposure equipment repeatedly forms a pattern on the wafer using laser light at a plurality of focus positions. Then, a pattern image by focus position for the pattern formed at the plurality of focus positions is collected. Next, a pixel histogram of the pattern images for each of the focus positions is derived. The extracted pattern image may be selected as a reference pattern image, and a reference DW value of the reference pattern image may be derived. Then, an upper DW value and a lower DW value may be set using the reference DW value according to the preset criteria.

The outlier detector 230 may calculate a DW value for each focus position and calculates a DW curve using the plurality of calculated DW values, and the outlier detector 230 may select an inflection point of the DW curve as an optimal focus position. Further, the outlier detector 230 may select an upper DW value and a lower DW value based on the optimal focus position according to the preset criteria after deriving the optimal focus position.

Further, the outlier detector 230 may derive an outlier generation level, an outlier generation location, and an outlier generation time, respectively.

The outlier detector 230 may detect the level of outlier generation by considering characteristics that cause the pattern images collected for each focus position to yield different DW values. The outlier detector 230 may apply the backer similarity-based method and the SSIM technique to derive the outlier generation location. Furthermore, the DW value variation results for each day of the exposure process may be used to derive the time of the outlier generation. The outlier detector 230 may be implemented as a computer program in a non-transitory computer readable medium storing computer programs.

The semiconductor exposure system 200 of example embodiments may further include a cause detector 240 and a history manager 250. The outlier detector 230, the cause detector 240 and the history manager 250 may be implemented as applications or may be implemented in the form of program commands that can be executed through various computer components and may be recorded on a computer-readable recording medium. The computer-readable recording medium may include program commands, data files, data structures, etc., alone or in combination. The program commands recorded on the computer-readable recording medium may be those specially designed and configured for the present invention or may be those known and available to those skilled in the art of computer software. Examples of the computer-readable recording medium may include magnetic media such as hard disks, floppy disks, and magnetic tapes, optical recording media such as CDROMs and DVDs, magneto-optical media such as floptical disks, and hardware devices specially configured to store and execute program commands such as ROMs, RAMs, and flash memories. Examples of the program commands may include not only machine language codes generated by a compiler, but also high-level language codes that can be executed by a computer using an interpreter, etc. The hardware device may be configured to operate as one or more software modules, and vice versa. The outlier detector 230, the cause detector 240 and the history manager 250 in the semiconductor exposure system 200 of example embodiments have a structure that is equipped with a computer, a program, and a memory in a composite manner, which is composed of one or more components.

The cause detector 240 may serve to derive outlier factors that are identified as contributing to the generation of the outlier.

The cause detector 240 may derive a correlation between the plurality of anomalies and the level of variation of the DW value, derive a major outlier that has a major effect on the variation of the DW value from the plurality of anomalies, generate a control signal to control a process variable associated with the major outlier, and provide the control signal to the pattern former 210.

Specifically, the cause detector 240 may build a machine learning model based on the DW value and a plurality of various process and equipment-related variables that may affect the change of the DW value, and the machine learning model may determine whether the DW value is normal or abnormal when the process and equipment-related variables are combined at a certain level. Then, after patterning a new wafer, when the DW value is extracted, it has the ability to notify the manager when the DW value exceeds the upper and lower management limits of the DW value level recognized by the existing machine learning model. In addition, it might notify the manager of which part of the wafer's pattern image is abnormal and at what level by comparing it with the existing machine learning model's database of pattern images of other wafers.

Furthermore, when the combination of multiple different process and equipment variables for these new wafers and the resulting DW values are normal, the machine learning model may add this data to the existing data held by the model and recognize it, thereby enhancing its ability to identify normal data.

Similarly, when the combination of multiple process and equipment variables and the resulting DW values for a new wafer are abnormal, the machine learning model will add this data to the existing data held by the model, but when the combination of multiple process and equipment variables and the resulting DW values for another wafer in the future are similar to the case of the abnormal wafer, the trained machine learning model will be able to recognize and flag it as abnormal data.

There are not separate machine learning models for normal data and machine learning models for anomalous data, but rather a mixture of normal and anomalous data in one machine learning model.

The machine learning model may be configured to receive outlier pattern images for patterns that are determined to be anomalous, and to iteratively perform machine learning on the outlier types in advance. The machine learning model may apply machine learning algorithms to learn correlations between outlier generation factors and levels of variation in DW values to derive key outlier generation factors based on their contribution (Feature Importance). The cause detector 240 provides the machine learning model generated by the above method and the contribution (feature importance) of the main factors contributing to the outlier to the outlier detector 230 in order of priority. Further, the outlier detector 230 may include a function to predict and simulate, based on the data in the machine learning model, which of the factors with high contribution to the generation of the outlier may be improved to a certain level so that the DW value may regress to a normal level, and the level of the DW value at that point.

The history manager 250 may serve to perform history management of DW values and outlier generation factors produced by photolithography process and exposure equipment included in the semiconductor exposure system. The DW value calculated from the pattern image may objectively describe patterning characteristics without limitation of the type and form of the exposure process and exposure equipment.

The history manager 250 may collect and store history information such as the process of the photolithography process, equipment conditions and equipment conditions of the exposure equipment included in the pattern forming, the pattern image, a pixel histogram derived from the pattern image, a DW value derived from the pattern image, a DW curve generated from the DW value, an outlier level, an outlier location, an outlier time, an outlier factor, and the like. The history manager 250 may provide the stored history information to the cause detector 240.

Furthermore, the history manager 250 may provide history information stored by the cause detector 240 to provide simulation results that suggest an effect on improving patterning performance.

The semiconductor exposure method according to the above-described embodiment derives a pixel histogram from a pattern image of the pattern to be analyzed, and calculates a DW value of the pattern using the derived pixel histogram. The DW value of the pattern may clearly numerically express the level of change in physical interaction due to a change in focus of the laser light, so that it is possible to accurately derive an outlier of the pattern caused by an excessive change in focus, the level of outlier of the pattern, the time of outlier of the pattern, the location of the outlier of the pattern, the risk of outlier of the pattern in the future, and the like.

Furthermore, the semiconductor exposure method according to the embodiments is highly versatile, as the DW value of the pattern may clearly numerically express the level of physical interaction with the laser focus change even when utilizing various exposure equipment from different manufacturers, enabling generalization of the focus position evaluation.

In addition, the semiconductor exposure method according to the embodiment may accurately identify the defocus trend, management level, and change level of the exposure process, and may objectively compare the actual process of each of the plurality of exposure equipment, equipment performance differences, and condition differences between the process and equipment without relying on the subjective judgment of the person in charge.

Furthermore, the semiconductor exposure method according to an embodiment may accurately extract the characteristics of the focus change from the pattern image by analyzing the correlation between the patterning conditions and the outlier generation factors of the exposure equipment on the focus of the laser light and the pattern image change, and may provide reliable outlier prediction results, causes, and improvement levels through machine learning based on AI.

Furthermore, the semiconductor exposure method according to an embodiment may be adjusted to place the laser light in an optimal focus position in the event of a defocus, thereby forming a clear ultra-fine pattern at a precise location on the wafer.

The semiconductor exposure method according to an embodiment may collect a pattern image for each focus position, and calculate a DW value for each focus position from the collected pattern image. Then, a DW curve may be generated from the calculated DW values for each focus position. Next, an inflection point of the generated DW curve may be identified, and the focus position at which the inflection point is located may be selected as an optimal focus position of the exposure equipment for performing the exposure process.

Therefore, the semiconductor exposure methods according to embodiments are applicable to semiconductor patterns that do not measure critical dimensions or are not the Bossung Curve in the form of a quadratic function with an inflection point, and may be utilized even when the density of semiconductor devices increases in the future due to the reliability of the derived optimal focus due to less variation depending on the wafer state, process, and equipment conditions.

The detailed description of the preferred embodiments of the present invention disclosed above has been provided to enable those skilled in the art to implement and practice the present invention. Although the above description has been provided with reference to preferred embodiments of the invention, it will be understood by those skilled in the art that various modifications and changes may be made to the invention without departing from the scope of the invention. For example, those skilled in the art may utilize each of the configurations described in the embodiments above in combination with each other. Accordingly, the invention is not intended to be limited to the embodiments shown herein, but rather to give the broadest scope consistent with the principles and novel features disclosed herein.

The invention may be embodied in other specific forms without departing from the spirit and essential features of the invention. Accordingly, the above detailed description is not to be construed as limiting in any respect and should be considered exemplary. The scope of the invention is to be determined by a reasonable interpretation of the appended claims, and all changes within the equivalents of the invention are included in the scope of the invention. The invention is not intended to be limited to the embodiments shown herein, but rather to give the broadest scope consistent with the principles and novel features disclosed herein. In addition, claims not expressly recited in the patent claims may be combined to form embodiments or included as new claims by post-filing amendment.

What is claimed is:

1. A semiconductor exposure method comprising:
forming a pattern on a wafer using a light source of a semiconductor exposure equipment;
collecting a pattern image of the pattern;
deriving a pixel histogram of the pattern image and calculating a dark or white value (DW value) of the pattern image from the pixel histogram; and
comparing the DW value of the pattern image with reference focus information to determine whether the light source is defocused.

2. The semiconductor exposure method of claim 1, wherein collecting the pattern image comprises collecting a critical dimension scanning electron microscope (CD-SEM) pattern image.

3. The semiconductor exposure method of claim 1, wherein calculating the DW value of the pattern image includes
dividing the pattern image into pixels;
classifying the pixels by brightness value to calculate a number of pixels for each brightness value; and
creating a scatter of the pixel histogram, and
wherein deriving the pixel histogram uses the number of pixels per brightness value.

4. The semiconductor exposure method of claim 1, wherein the reference focus information comprises a reference pattern image for a pattern formed at an optimal focus position, and a reference DW value, an upper DW value, and a lower DW value for the reference pattern image.

5. The semiconductor exposure method of claim 1, wherein calculating the reference focus information comprises:
repeatedly forming a pattern on the wafer with the light source at a plurality of focus positions using the semiconductor exposure equipment;
collecting a pattern image for each focus position for a pattern formed at the plurality of focus positions to derive a pixel histogram of the pattern image for each focus position, respectively;
deriving the DW value of each pattern image from the pixel histogram of the pattern image by focus position;
extracting a pattern image of a pattern formed at an optimal focus position of the light source, and selecting the extracted pattern image as a reference pattern image;
deriving a reference DW value for the reference pattern image; and
setting an upper DW value and a lower DW value using the reference DW value in accordance with a predetermined criterion.

6. The semiconductor exposure method of claim 1, wherein determining whether an outlier is generated in the pattern comprises detecting a level of the outlier of the pattern by comparing the DW value of the pattern image with the reference focus information when the light source is defocused and determining that the pattern is abnormal.

7. The semiconductor exposure method of claim 6, wherein detecting the level of the outlier comprises detecting an outlier generation level of the pattern using a vector similarity-based method, which includes at least one of Cross Correlation Distance, Chi-Square Distance, Intersection Distance, Bhattacharyya Distance, and Cosine Distance, wherein the vector similarity-based method quantifies the pattern image of the pattern into a vector by comparing a similarity of the pattern image to the reference focus information, and wherein the vector is used to detect the outlier generation level of the pattern to be analyzed.

8. The semiconductor exposure method of claim 7, wherein determining whether the outlier is generated in the pattern comprises, when the light source is defocused and the outlier is generated in the pattern, detecting the outlier generation level of the pattern using the DW value and the vector, and evaluating a structural similarity index measure (SSIM) of the pattern image and a reference pattern image to detect an outlier generation location and the outlier generation level of the pattern.

9. The semiconductor exposure method of claim 1, wherein determining whether an outlier is generated in the pattern comprises determining that the outlier is generated in the pattern due to a defocused light source, deriving a major outlier causing the outlier to occur, and presenting key outlier factors in order of priority.

10. The semiconductor exposure method of claim 9, wherein presenting the key outlier factors comprises extracting a feature of an outlier generation type of the pattern, and comparing a correlation between a plurality of outlier generation factors and a DW value variation level of the outlier generation type to derive a major outlier generation factor of the outlier generation type.

11. The semiconductor exposure method of claim 10, wherein determining whether the outlier is generated in the pattern further comprises deriving the major outlier generation factor and then controlling a process variable of a semiconductor exposure process associated with the major outlier generation factor.

12. The semiconductor exposure method of claim 11, wherein controlling the process variable of the semiconductor exposure process comprises generating and providing patterning prediction information based on the DW value derived when forming the pattern on the wafer with the semiconductor exposure equipment by controlling process variables of the semiconductor exposure equipment associated with the major outlier generation factor.

13. The semiconductor exposure method of claim 10, wherein presenting the key outlier factors further comprises generating process and equipment conditions for performing a semiconductor exposure process and a machine learning model for predicting anomalies in the semiconductor exposure equipment based on the DW value.

14. The semiconductor exposure method of claim 13, wherein the machine learning model predicts a time of outlier generation and a level of outlier generation based on the process and equipment conditions for performing the semiconductor exposure process, and a direction of change, a trend of change, and a level of change of the DW value.

15. The semiconductor exposure method of claim 14,
wherein the time of the outlier generation calculated by deriving trend direction and trend angle of the DW value from the change in the DW value over time, and
wherein the level of outlier generation is calculated using the trend angle.

16. The semiconductor exposure method of claim 14, wherein the machine learning model selects outlier generating factors related to the semiconductor exposure equipment and the semiconductor exposure process that are expected to have a large impact on the change of the DW value in consideration of the correlation with trend direction and trend angle of the DW value, and provides an improvement level result of the changed DW value by controlling the selected outlier generating factors through simulation.

17. The semiconductor exposure method of claim 10, wherein the key outlier factors comprises at least one of a focus position of the light source, an energy level of light, a breakage of the light source and lens installed in the semiconductor exposure equipment, an angle of incidence of the lens with the light produced by the light source, a contamination of the light source and the lens, a result of a wafer processing process performed prior to a semiconductor exposure process, a vibration of the semiconductor exposure equipment, and a plurality of conditions affecting the semiconductor exposure process.

18. A semiconductor exposure system comprising:
a pattern former configured to form a pattern on a wafer by performing an exposure process;
an image collector configured to collect a pattern image of the pattern to be analyzed; and
an outlier detector configured to derive a pixel histogram of the pattern image, to calculate a dark or white value (DW value) of the pattern image using the pixel histogram, and to compare the DW value of the pattern image to reference focus information to determine whether an outlier is generated corresponding to a focus of a light source in the pattern former.

19. The semiconductor exposure system of claim 18, wherein the semiconductor exposure system further comprises a cause detector configured to derive outlier factors that are identified as influencing the generation of the outlier.

20. The semiconductor exposure system of claim 19, wherein the semiconductor exposure system further comprises a history manager configured to collect and store history information including at least one of a process condition of the exposure process and an equipment condition of exposure equipment included in the pattern former, the pattern image, the pixel histogram derived from the pattern image, the DW value derived from the pattern image, a DW curve generated from the DW value, an outlier level, an outlier time, an outlier location, and the outlier factors, and providing the stored history information to the cause detector.
